(19) United States
(12) Patent Application Publication
(10) Pub. No.: US 2023/0387171 A1
(43) Pub. Date: Nov. 30, 2023

(54) DEEP TRENCH ISOLATION STRUCTURE IN A PIXEL SENSOR

(71) Applicant: Taiwan Semiconductor Manufacturing Company, Ltd., Hsinchu (TW)

(72) Inventors: Feng-Chien HSIEH, Pingtung City (TW); Yun-Wei CHENG, Taipei City (TW); Kuo-Cheng LEE, Tainan City (TW); Cheng-Ming WU, Tainan City (TW)

(21) Appl. No.: 18/364,734

(22) Filed: Aug. 3, 2023

Related U.S. Application Data
(62) Division of application No. 17/302,054, filed on Apr. 22, 2021.

(51) Int. Cl. H01L 27/146

(52) U.S. Cl. CPC H01L 27/1463; H01L 27/14636; H01L 27/14683; H01L 27/14649

(57) ABSTRACT

A pixel sensor may include a deep trench isolation (DTI) structure that extends the full height of a substrate in which a photodiode of the pixel sensor is included. Incident light entering the pixel sensor at a non-orthogonal angle is absorbed or reflected by the DTI structure along the full height of the substrate. In this way, the DTI structure may reduce, minimize, and/or prevent the incident light from traveling through the pixel sensor and into an adjacent pixel sensor along the full height of the substrate. This may increase the spatial resolution of an image sensor in which the DTI structure is included, may increase the overall sensitivity of the image sensor, may reduce and/or prevent color mixing between pixel sensors of the image sensor, and/or may decrease image noise after color correction.

### RELATED APPLICATION

This application is a divisional of U.S. patent application Ser. No. 17/302,054, filed Apr. 22, 2021, which is incorporated herein by reference in its entirety.

### BACKGROUND

Complementary metal oxide semiconductor (CMOS) image sensors utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CMOS image sensor is often based on the three primary colors: red, green, and blue (R, G, B). Pixel sensors that sense light for each color can be defined through the use of a color filter that allows the light wavelength for a particular color to pass into a photodiode. Some pixel sensors may be configured as white pixel sensors such that multiple colors of incident light are permitted through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2 and 3 are diagrams of example pixel arrays described herein.

FIGS. 4A-4E are diagrams of an example pixel sensor described herein.

FIGS. 5A-5W are diagrams of an example implementation described herein.

FIGS. 6 and 7 are diagrams of example pixel sensors described herein.

FIGS. 8A-8D are diagrams of an example implementation described herein.

FIG. 9 is a diagram of an example pixel sensor described herein.

FIGS. 10A-10H are diagrams of an example implementation described herein.

FIGS. 11A-11H are diagrams of example pixel arrays described herein.

FIG. 12 is a diagram of example light absorption data described herein.

FIG. 13 is a diagram of example components of one or more devices of FIG. 1.

FIG. 14 is a flowchart of an example process relating to forming a pixel array.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Optical crosstalk can occur between adjacent pixel regions in a pixel array. Optical crosstalk is a pixel array performance issue, whereby incident light passes through a pixel sensor at a non-orthogonal angle and is at least partially absorbed by a photodiode of an adjacent pixel sensor. Optical crosstalk in a pixel array of an image sensor can degrade the spatial resolution of the image sensor, can reduce overall sensitivity of the image sensor, can cause color mixing between pixel sensors of the image sensor, and/or can lead to image noise after color correction.

Some implementations described herein provide pixel sensors that include full deep trench isolation (DTI) structures to reduce, minimize, and/or prevent optical crosstalk in an image sensor. A full DTI structure may include a DTI structure that extends the full height of a substrate in which a pixel sensing region (e.g., a region that includes a photodiode) of a pixel sensor is included. Incident light entering the pixel sensor at a non-orthogonal angle is absorbed or reflected by the full DTI structure along the full height of the substrate. In this way, the full DTI structure may reduce, minimize, and/or prevent the incident light from traveling through the pixel sensor and into an adjacent pixel sensor along the full height of the substrate. This may increase the spatial resolution of an image sensor in which the full DTI structure is included, may increase the overall sensitivity of the image sensor, may reduce and/or prevent color mixing between pixel sensors of the image sensor, and/or may decrease image noise after color correction.

Some implementations described herein provide various configurations of pixel arrays that include visible light pixel sensors to obtain color information and white pixel sensors (or clear pixel sensors) to improve low-light performance and/or night vision. One or more of the pixel sensors in the pixel arrays described herein may include extended conductive structures to reflect visible light toward the photodiodes of the pixel sensors and an absorption layer on the extended conductive structures to absorb infrared light. The extended conductive structures may be extended to increase the amount of reflected visible light, which may increase the quantum efficiency of the pixel sensors, may increase the low-light color performance of the pixel sensors, and may enable full-color night vision image sensors.

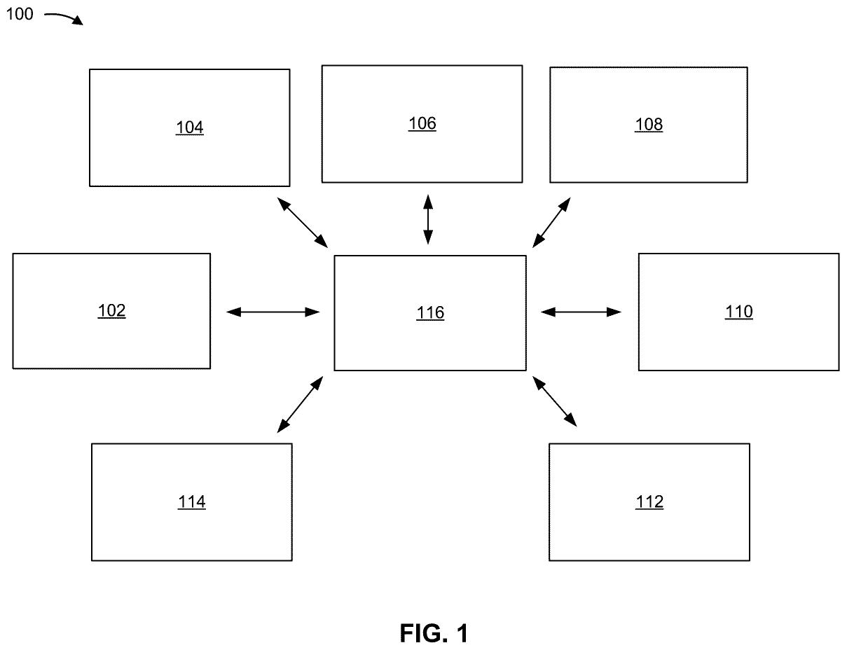

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

Wafer/die transport tool 116 includes a mobile robot, a robot arm, a tram or rail car, an overhead hoist transport (OHT) system, an automated materially handling system (AMHS), and/or another type of device that is used to transport wafers and/or dies between semiconductor processing tools 102-114 and/or to and from other locations such as a wafer rack, a storage room, and/or the like. In some implementations, wafer/die transport tool 116 may be a programmed device that is configured to travel a particular path and/or may operate semi-autonomously or autonomously.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

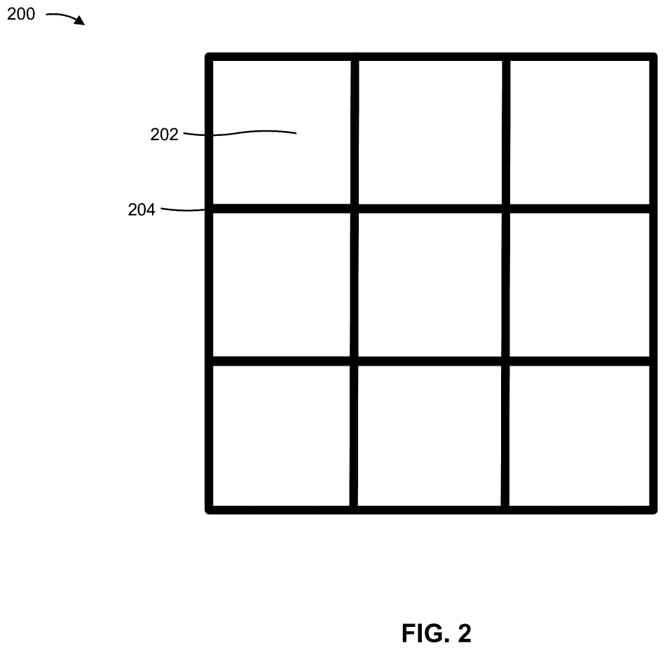

FIG. 2 shows a top-down view of the pixel array 200. In some implementations, the pixel array 200 may be included in an image sensor. The image sensor may include a complementary metal oxide semiconductor (CMOS) image sensor, a back side illuminated (BSI) CMOS image sensor, a front side illuminated (FSI) CMOS image sensor, or another type of image sensor. As shown in FIG. 2, the pixel array 200 may include a plurality of pixel sensors 202. As further shown in FIG. 2, the pixel sensors 202 may be arranged in a grid. In some implementations, the pixel sensors 202 are square-shaped (as shown in the example in FIG. 2). In some implementations, the pixel sensors 202 include other shapes such as circle shapes, octagon shapes, diamond shapes, and/or other shapes.

The pixel sensors 202 may be configured to sense and/or accumulate incident light (e.g., light directed toward the pixel array 200). For example, a pixel sensor 202 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

The pixel sensors 202 may be electrically and optically isolated by a DTI structure 204 included in the pixel array 200. The DTI structure 204 may include a plurality of interconnected trenches that are filled with a dielectric material such as an oxide. The trenches of the DTI structure 204 may be included around the perimeters of the pixel sensors 202 such that the DTI structure 204 surrounds the pixel sensors 202, as shown in FIG. 2. Moreover, the trenches of the DTI structure 204 may extend into a substrate in which the pixel sensors 202 are formed to surround the photodiodes and other structures of the pixel sensors 202 in the substrate.

The pixel array 200 may be electrically connected to a back-end-of-line (BEOL) metallization stack (not shown) of the image sensor. The BEOL metallization stack may electrically connect the pixel array 200 to control circuitry that may be used to measure the accumulation of incident light in the pixel sensors 202 and convert the measurements to an electrical signal.

As indicated above, FIG. 2 is provided as an example. Other examples may differ from what is described with regard to FIG. 2.

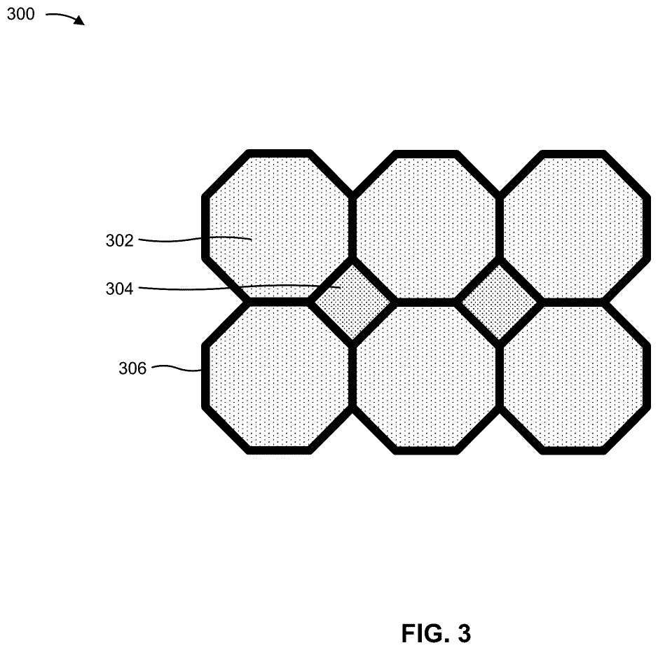

FIG. 3 is a diagram of an example pixel array 300 described herein. In some implementations, the pixel array 300 may be included in an image sensor. The image sensor may be a CMOS image sensor, a BSI CMOS image sensor, or another type of image sensor. As shown in FIG. 3, the pixel array 300 may include a plurality of octagon-shaped pixel sensors 302 and a plurality of square-shaped pixel sensors 304. The octagon-shaped pixel sensors 302 and the square-shaped pixel sensors 304 may be interspersed, intermixed, and/or distributed throughout the pixel array 300.

As shown in FIG. 3, a square-shaped pixel sensor 304 may be disposed between and/or surrounded by a subset of octagon-shaped pixel sensors 302 (e.g., 4 octagon-shaped pixel sensors 302) such that the sides of the octagon-shaped pixel sensors 302 align with the sides of the square-shaped pixel sensors 304. This reduces and/or minimizes unused gaps or portions between the pixel sensors of the pixel array 300, which increases the pixel sensor density of the pixel array 300 and increases spatial utilization in the pixel array 300.

Moreover, this particular arrangement permits the length of the sides of the octagon-shaped pixel sensors 302 to be adjusted to increase or decrease the size of the square-shaped pixel sensors 304 while maintaining the tight grouping of pixel sensors in the pixel array 300. For example, the length of the sides of octagon-shaped pixel sensors 302 facing a square-shaped pixel sensor 304 may be decreased to correspondingly decrease the size of the square-shaped pixel sensor 304. As another example, the length of the sides of octagon-shaped pixel sensors 302 facing a square-shaped pixel sensor 304 may be increased to correspondingly increase the size of the square-shaped pixel sensor 304. In addition, this particular arrangement permits the square-shaped pixel sensors 304 to be used with regular octagon-shaped pixel sensors (e.g., octagon-shaped pixel sensors having all sides the same length) and/or irregular octagon-shaped pixel sensors (e.g., octagon-shaped pixel sensors having two or more sides of different lengths).

The octagon-shaped pixel sensors 302 and the sides of the square-shaped pixel sensors 304 may be electrically and optically isolated by a DTI structure 306 included in the pixel array 300. The trenches of the DTI structure 306 may be included around the perimeters of the octagon-shaped pixel sensors 302 and the sides of the square-shaped pixel sensors 304 such that the DTI structure 306 surrounds the octagon-shaped pixel sensors 302 and the sides of the square-shaped pixel sensors 304, as shown in FIG. 3. Moreover, the trenches of the DTI structure 306 may extend into a substrate in which the octagon-shaped pixel sensors 302 and the sides of the square-shaped pixel sensors 304 are formed to surround the photodiodes and other structures of the octagon-shaped pixel sensors 302 and the sides of the square-shaped pixel sensors 304 in the substrate.

As indicated above, FIG. 3 is provided as an example. Other examples may differ from what is described with regard to FIG. 3.

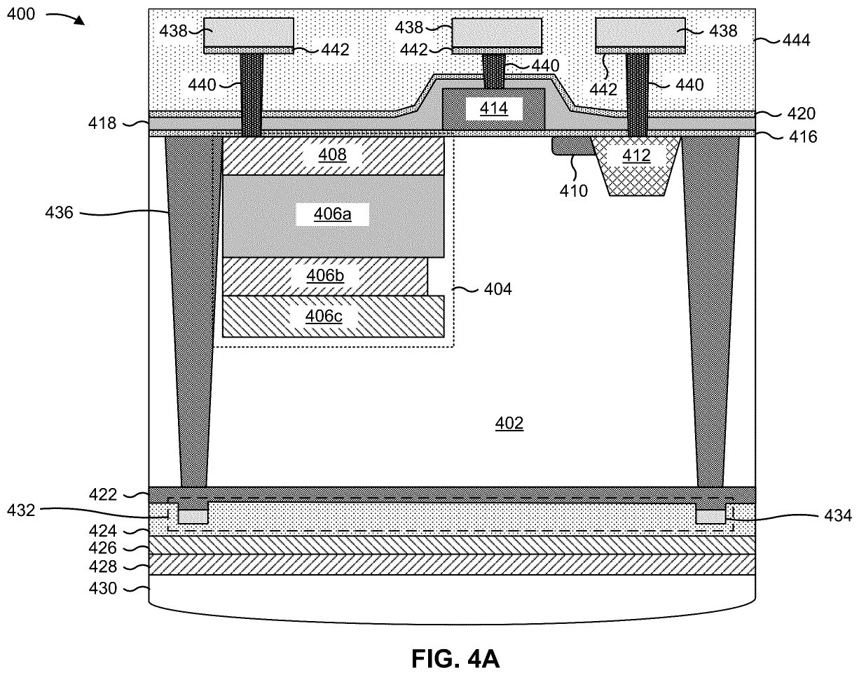

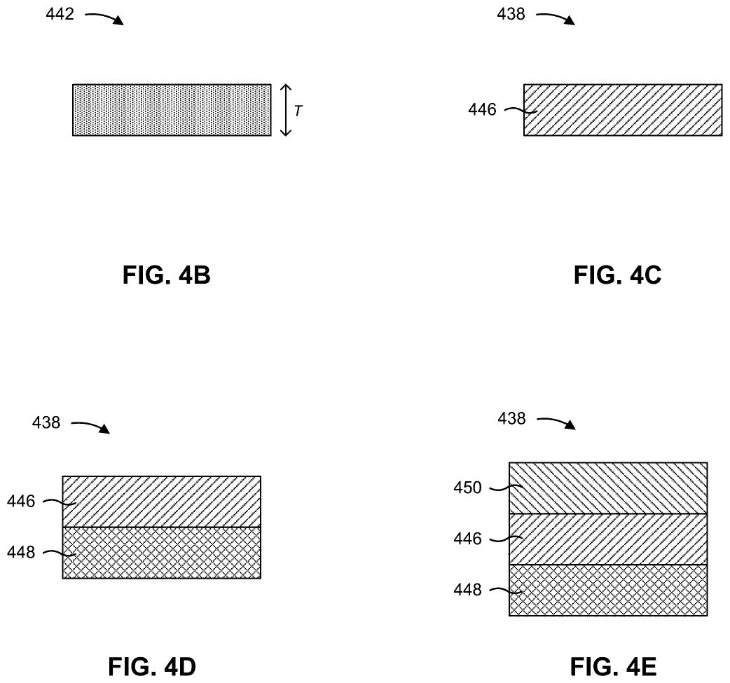

FIGS. 4A-4E are diagrams of an example pixel sensor 400 described herein. The pixel sensor 400 may include a full DTI structure that that extends through a substrate on a first side (e.g., a top surface) of the substrate and on a second side (e.g., a bottom surface) of the substrate to provide increased crosstalk performance for the pixel sensor 400. In some implementations, the pixel sensor 400 may be configured as and/or may implement a pixel sensor 202 and be included in the pixel array 200. In some implementations, the pixel sensor 400 may be configured as an octagon-shaped pixel sensor 302 or a square-shaped pixel sensor 304, and may be included in the pixel array 300. In some implementations, the pixel sensor 400 may be included in an image sensor. The image sensor may be a CMOS image sensor, a BSI CMOS image sensor, or another type of image sensor.

FIG. 4A illustrates a cross-section view of the pixel sensor 400. As shown in FIG. 4A, the pixel sensor 400 may include a substrate 402. The substrate 402 may include a semiconductor die substrate, a semiconductor wafer, or another type of substrate in which semiconductor pixels may be formed. In some implementations, the substrate 402 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 402 is formed of a doped material (e.g., a p-doped material or an n-doped material) such as a doped silicon.

The pixel sensor 400 may include a photodiode 404 included in the substrate 402. The photodiode 404 may include a plurality of regions that are doped with various types of ions to form a p-n junction or a PIN junction (e.g., a junction between a p-type portion, an intrinsic (or undoped) type portion, and an n-type portion). For example, the substrate 402 may be doped with an n-type dopant to form one or more n-type regions 406 of the photodiode 404, and the substrate 402 may be doped with a p-type dopant to form a p-type region 408 of the photodiode 404. The photodiode 404 may be configured to absorb photons of incident light. The absorption of photons causes the photodiode 404 to accumulate a charge (referred to as a photocurrent) due to the photoelectric effect. Photons may bombard the photodiode 404, which causes emission of electrons in the photodiode 404.

The regions included in the photodiode 404 may be stacked and/or vertically arranged. For example, the p-type region 408 may be included over the one or more n-type regions 406. The p-type region 408 may provide noise isolation for the one or more n-type regions 406 and may facilitate photocurrent generation in the photodiode 404. The one or more n-type regions 406 may include an n-type region 406a, an n-type region 406b, and an n-type region 406c. The n-type region 406b may be located over and/or on the n-type region 406c, and the n-type region 406a may be located over and/or on the n-type region 406b. The n-type region 406b and the n-type region 406c may be referred to as deep n-type regions or deep n-wells and may extend the n-type region 406 of the photodiode 404. These deep n-type regions may provide an increased area for photon absorption in the photodiode 404. Moreover, at least a subset of the one or more n-type regions 406 may have different doping concentrations. For example, the n-type region 406a may include a greater n-type dopant concentration relative to the n-type region 406b and the n-type region 406c, and the n-type region 406b may include a greater n-type dopant concentration relative to the n-type region 406c. As a result, an n-type dopant gradient is formed, which may increase the migration of electrons upward in the photodiode 404.

The pixel sensor 400 may include a drain extension region 410 and a drain region 412 coupled and/or electrically connected to the drain extension region 410. The drain extension region 410 may be adjacent to the drain region 412. The drain region 412 may include a highly-doped n-type region (e.g., an n⁺ doped region). The drain extension region 410 may include lightly-doped n-type region(s) that facilitate the transfer of photocurrent from the n-type region 406a to the drain region 412.

The pixel sensor 400 may include a transfer gate 414 to control the transfer of photocurrent between the photodiode 404 and the drain region 412. The transfer gate 414 may be energized (e.g., by applying a voltage or a current to the transfer gate 414) to cause a conductive channel to form in the substrate 402 between the photodiode 404 and the drain extension region 410. The conductive channel may be removed or closed by de-energizing the transfer gate 414, which blocks and/or prevents the flow of photocurrent between the photodiode 404 and the drain region 412. In some implementations, the transfer gate 414 includes a poly gate that includes polysilicon, a doped polysilicon (e.g., n⁺ doped polysilicon), or a combination thereof. In some implementations, the transfer gate 414 includes a metal gate that includes one or more metals.

A gate dielectric layer 416 may be included above and/or over the top surface of the substrate 402. The gate dielectric layer 416 may include a dielectric material such as tetraethyl orthosilicate (TEOS) or another type of dielectric material. An oxide layer 418 may be included over and/or on the gate dielectric layer 416. The oxide layer 418 may also be included on sidewalls of the transfer gate 414. The oxide layer 418 may include an oxide such as silicon oxide (SiOₓ) or another type of oxide material. The oxide layer 418 may be configured as a remote plasma oxide (RPO) layer, a gate oxide layer, and/or another type of oxide layer. A contact etch stop layer (CESL) 420 may be included over and/or on the oxide layer 418 over the top surface of the substrate 402. The contact etch stop layer 420 may include a silicon oxynitride (SiONₓ), a silicon carbon nitride (SiCNₓ), a silicon nitride (SiNₓ), a silicon carbide (SiCₓ), and/or another type of etch stop material.

As described above, the pixel sensor 400 may be included in a BSI CMOS image sensor. Accordingly, the pixel sensor 400 may include one or more layers on a back side or a bottom side of the substrate 402. An oxide layer 422 may be included over and/or on the bottom side of the substrate 402. The oxide layer 422 may be configured as a passivation layer between the substrate 402 and other layers on the back side of the pixel sensor 400. In some implementations, the oxide layer 422 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another type of dielectric material is used in place of the oxide layer 422 as a passivation layer.

A dielectric layer 424 may be included over and/or on the oxide layer 422. The dielectric layer 424 may include a dielectric material such as a silicon oxide (SiOₓ) (e.g., silicon dioxide (SiO₂)). An antireflective coating (ARC) 426 may be included over and/or on the dielectric layer 424. The ARC 426 may include a suitable material for reducing a reflection of incident light projected toward the photodiode 404. For example, the ARC 426 may include a nitrogen-containing material.

A color filter layer 428 may be included above and/or on the ARC 426. In some implementations, the color filter layer 428 includes a visible light color filter configured to filter a particular wavelength or a particular wavelength range of visible light (e.g., red light, blue light, or green light). In some implementations, the color filter layer 428 includes a near infrared (NIR) filter (e.g., a NIR bandpass filter) configured to permit wavelengths associated with NIR light to pass through the color filter layer 428 and to block other wavelengths of light. In some implementations, the color filter layer 428 includes a NIR cut filter configured to block NIR light from passing through the color filter layer 428. In some implementations, the color filter layer 428 includes a non-filtering material or is omitted from the pixel sensor 400 to permit all wavelengths of light to pass through to the photodiode 404. In these examples, the pixel sensor 400 may be configured as a white pixel sensor.

A micro-lens layer 430 may be included above and/or on the color filter layer 428. The micro-lens layer 430 may include a micro-lens for the pixel sensor 400 configured to focus incident light toward the photodiode 404 and/or to reduce optical crosstalk between the pixel sensor 400 and adjacent pixel sensors.

A grid structure 432 may be included over the back side of the pixel sensor 400. The grid structure 432 may include a plurality of interconnected columns that surround the perimeter of the pixel sensor 400, and may be configured to provide crosstalk reduction and/or mitigation. The grid structure 432 may include portions of the oxide layer 422 and portions of a metal layer 434 on the portions of the oxide layer 422. The metal layer 434 may include a metallic material such as tungsten (W), copper (Cu), aluminum (Al), cobalt (Co), nickel (Ni), titanium (Ti), tantalum (Ta), another type of conductive material, and/or an alloy including one or more of the foregoing. The metal layer 434 may be configured to reflect a portion of incident light to reduce optical crosstalk.

The photodiode 404 of the pixel sensor 400 may be electrically and optically isolated from adjacent pixel sensors by a DTI structure 436. The DTI structure 436 may surround the photodiode 404 and, thus, the n-type regions 406 and the p-type region 408 included therein. Moreover, the DTI structure 436 may surround the drain extension region 410 and the drain region 412. In some implementations, the DTI structure 436 may include the DTI structure 204 included in the pixel array 200 and/or the DTI structure 306 included in the pixel array 300.

The DTI structure 436 may include a plurality of interconnecting trenches that extend into the substrate 402 around the photodiode 404, the drain extension region 410, and the drain region 412. The DTI structure 436 may provide optical isolation between adjacent pixel sensors in the pixel sensor 400 to reduce the amount of optical crosstalk between adjacent pixel sensors. In particular, DTI structure 436 may absorb, refract, and/or reflect incident light, which may reduce the amount of incident light that travels through a pixel sensor 400 into an adjacent pixel sensor and is absorbed by the adjacent pixel sensor. Moreover, the DTI structure 436 may reflect incident light toward the photodiode 404, thereby increasing the amount of incident light that is absorbed by the photodiode 404 (which increases the quantum efficiency of the pixel sensor 400). The DTI structure 436 may be filled with an oxide material such as a silicon oxide (SiOₓ) (e.g., silicon dioxide (SiO₂)) and/or another type of oxide material.

The DTI structure 436 may be referred to as a full DTI structure 436 in that the DTI structure 436 extends through the full height of the substrate 402 from a first side (e.g., the top surface or front side) of the substrate 402 to a second side (e.g., the bottom surface or back side) of the substrate 402. In this way, the DTI structure 436 may absorb, refract, and/or reflect incident light along the full height or the full thickness of the substrate, which may further reduce optical crosstalk and may further increase the quantum efficiency of the pixel sensor 400. In some implementations, the height (or the depth) of the DTI structure 436 may be in a range of approximately 1 micron (e.g., to provide sufficient isolation performance) and approximately 9 microns (e.g., to provide sufficient leakage performance and to avoid excessive damage to the substrate 402). However, other values for the height (or the depth) of the DTI structure 436 are within the scope of the present disclosure.

As shown in FIG. 4, the DTI structure 436 may taper from the first side (e.g., the top surface or front side) of the substrate 402 to the second side (e.g., the bottom surface or back side) of the substrate 402 such that the width of the DTI structure 436 decreases from the first side (e.g., the top surface or front side) of the substrate 402 to the second side (e.g., the bottom surface or back side) of the substrate 402. This is due to the DTI structure 436 being etched into the substrate 402 from the first side (e.g., the top surface or front side) of the substrate 402. The etch rate, when forming the DTI structure 436, may be greater near the first side (e.g., the top surface or front side) of the substrate 402 relative to the second side (e.g., the bottom surface or back side) of the substrate 402 due to the etchant that is used to etch the DTI structure 436 being in contact for a greater duration near the first side (e.g., the top surface or front side) of the substrate 402 relative to the second side (e.g., the bottom surface or back side) of the substrate 402.

The transfer gate 414, the drain region 412, and/or other structures of the pixel sensor 400 may be electrically connected with a metallization layer, above the substrate 402, that includes a plurality of conductive structures 438. The conductive structures 438 may be included in a BEOL region and/or a middle end of line (MEOL) region of the image sensor in which the pixel sensor 400 is included, and may electrically connect the pixel sensor 400 to other devices and/or structures in the image sensor and/or to external packaging of the image sensor. The conductive structures 438 may include trenches, vias, and/or other types of BEOL structures and/or MEOL structures, and may be formed of various types of materials including one or more types of metals, metal alloys, or a combination thereof.

The conductive structures 438 may also be configured to reflect incident light that travels through the substrate 402 back toward the photodiode 404. In this way, the reflected incident light may be absorbed by the photodiode 404, which increases the quantum efficiency of the photodiode 404. The size (or area) of the conductive structures may be configured to achieve and/or provide a particular light reflection performance. For example, a ratio between the area of the conductive structures 438, and an area of a dielectric layer 444, may be in a range of approximately 0.3 to approximately 1.5 to provide sufficient light reflection performance. However, other values for the ratio are within the scope of the present disclosure. The ratio may be increased or decreased to respectively increase or decrease the light reflection performance of the conductive structures 438.

The conductive structures 438 may be electrically connected to the transfer gate 414, the drain region 412, and/or other structures of the pixel sensor 400 by interconnect structures 440. The interconnect structures 440 may include contact plugs, vias, and/or other types of structures. The interconnect structures 440 may each be filled with a conductive material, such as tungsten, cobalt, ruthenium, and/or another type of conductive material.

An absorption layer 442 may be included on a surface of the conductive structures 438 that faces the substrate 402. The absorption layer 442 may be configured to absorb infrared light (e.g., an infrared component of incident light) that travels through the substrate 402. The absorption layer 442 may absorb infrared light, which reduces the amount of infrared light that is absorbed by the photodiode 404. This may decrease noise that might otherwise be caused by the infrared light in images and/or video that is generated based on the photocurrent generated by the photodiode 404, may increase color accuracy (e.g., as the infrared light might otherwise result in elevated and inaccurate photocurrents), and/or may increase photosensitivity (e.g., as the infrared light might otherwise reduce the sensitivity of the photodiode 404), among other examples.

In some implementations, the absorption layer 442 is omitted from the conductive structures 438 such that infrared light is reflected toward the photodiode 404 by the conductive structures 438. This configuration may be implemented, for example, in an NIR pixel sensor in which the photodiode 404 is configured to absorb and measure infrared light.

The conductive structures 438, the interconnect structures 440, and the absorption layer 442 may be included in the dielectric layer 444 over the substrate 402. The dielectric layer 444 may include an intermetal dielectric (IMD) formed of an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), an aluminum oxide (AlOₓ), or another type of dielectric material.

FIG. 4B illustrates an example configuration of the absorption layer 442. As shown in FIG. 4B, the absorption layer 442 may be formed to a thickness (7). The thickness (7) of the absorption layer 442 may be in a range of approximately 10 angstroms (e.g., to provide sufficient infrared light absorption performance) to approximately 500 angstroms (e.g., to maintain a sufficiently low contact resistance between the conductive structures 438 and the interconnect structures 440). However, other values for the thickness (7) of the absorption layer 442 are within the scope of the present disclosure. The absorption layer 442 may include various types of dielectric materials and/or other types of materials that are capable of absorbing infrared light and/or light having a wavelength greater than approximately 750 nanometers. In some implementations, the absorption layer 442 includes a silicon oxide (SiₓO_{y}), tantalum (Ta), a tantalum nitride (TaₓN_{y}), or a combination thereof. In some implementations, the absorption layer 442 includes a combination of tantalum and a tantalum nitride, where the ratio between the tantalum nitride and the tantalum is in a range of approximately 0.1 to approximately 2. However, other values for the ratio are within the scope of the present disclosure.

FIGS. 4C-4E illustrate various example configurations of conductive structures 438. As described above, the conductive structures 438 may be configured to reflect the visible light component of incident light, which may include incident light in wavelength range of approximately 350 nanometers to approximately 750 nanometers or greater. As shown in FIG. 4B, a conductive structure 438 may include a layer 446 of metal material, such as gold (Au), silver (Ag), copper (Cu), aluminum (Al), another type of highly reflective metal, an alloy thereof, or a combination thereof. The metal material may reflect incident light toward the photodiode 404 of the pixel sensor 400, which may increase the quantum efficiency of the pixel sensor 400. In some implementations, gold may be used in implementations where the incident light into the pixel sensor 400 is estimated to include shorter wavelengths of light, such as in a range of approximately 200 nanometers to approximately 600 nanometers. In some implementations, aluminum may be used in implementations where the incident light into the pixel sensor 400 is estimated to include relatively longer wavelengths of light, such as in a range of approximately 650 nanometers to approximately 1250 nanometers.

As shown in FIG. 4D, a conductive structure 438 may include two layers of metal material, such as the layer 446 and layer 448. The layer 448 may include tungsten or another metal that, in combination with the metal material of the layer 446, further increases the light reflection performance of the conductive structure 438. In some implementations, the layer 446 is included over and/or on the layer 448. In some implementations, the layer 448 is included over and/or on the layer 446.

As shown in FIG. 4E, a conductive structure 438 may include three layers of metal material, such as the layer 446, the layer 448, and layer 450. The layer 450 may include a metal material such as gold (Au), silver (Ag), copper (Cu), aluminum (Al), another type of highly reflective metal, an alloy thereof, or a combination thereof. In some implementations, the layer 446 and the layer 450 may include the same metal material. In some implementations, the layer 446 and the layer 450 may include different metal materials. The layer 446 and the layer 450 may include different metal materials to increase the light reflection performance of the conductive structure 438 across a wider range of light wavelengths. As an example, the layer 446 may include gold to reflect shorter wavelengths of light, and the layer 450 may include aluminum to reflect longer wavelengths of light. In some implementations, the layer 450 is included over and/or on the layer 446, and the layer 446 is included over and/or on the layer 448. In some implementations, the layer 448 is included in between the layer 446 and the layer 450. In some implementations, a conductive structure 438 may include four or more layers of metal material to further increase the light reflection performance of the conductive structure 438, which increases the height/thickness of the conductive structure 438.

As indicated above, FIGS. 4A-4E are provided as one or more examples. Other examples may differ from what is described with regard to FIGS. 4A-4E.

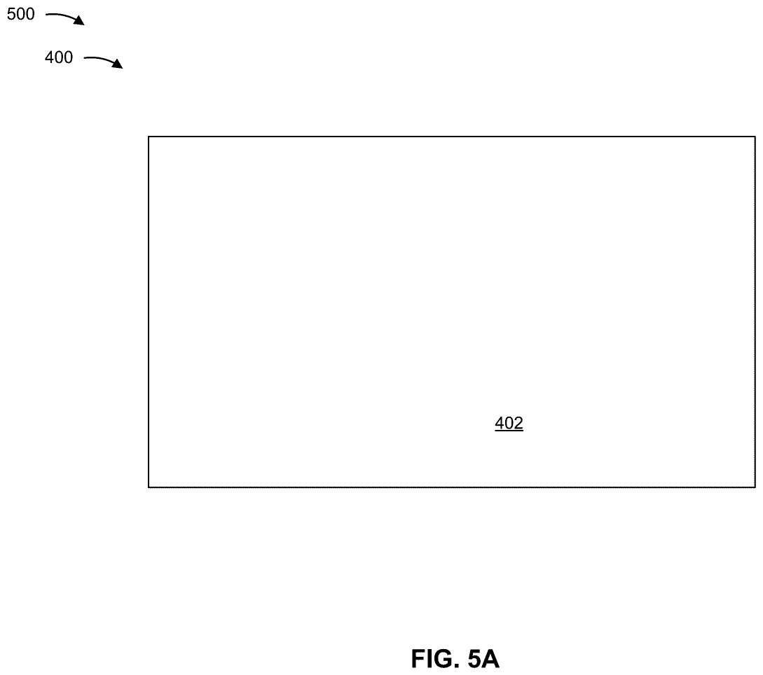

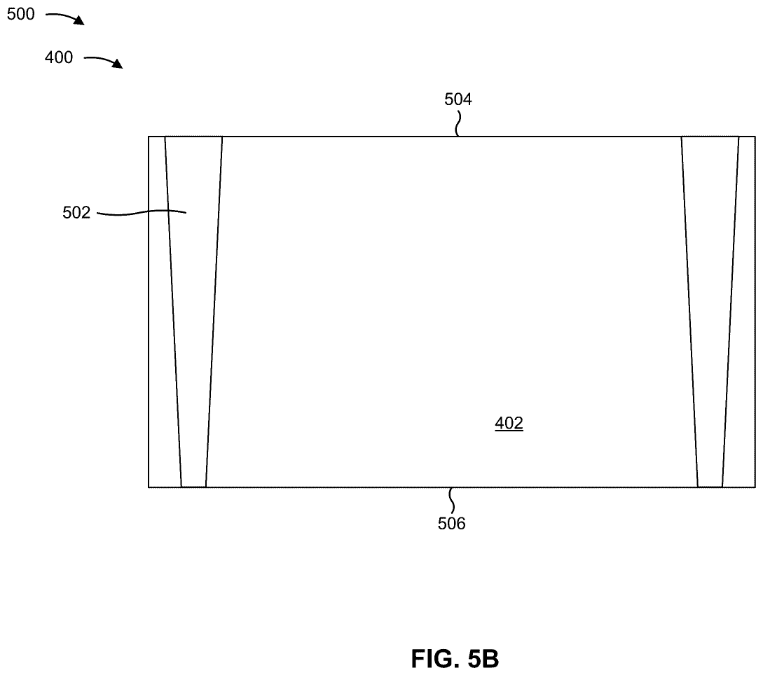

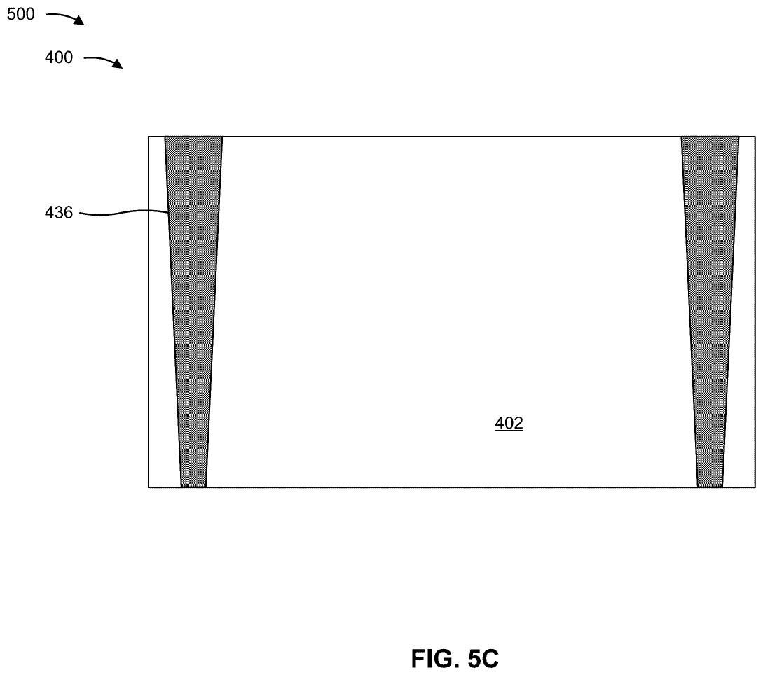

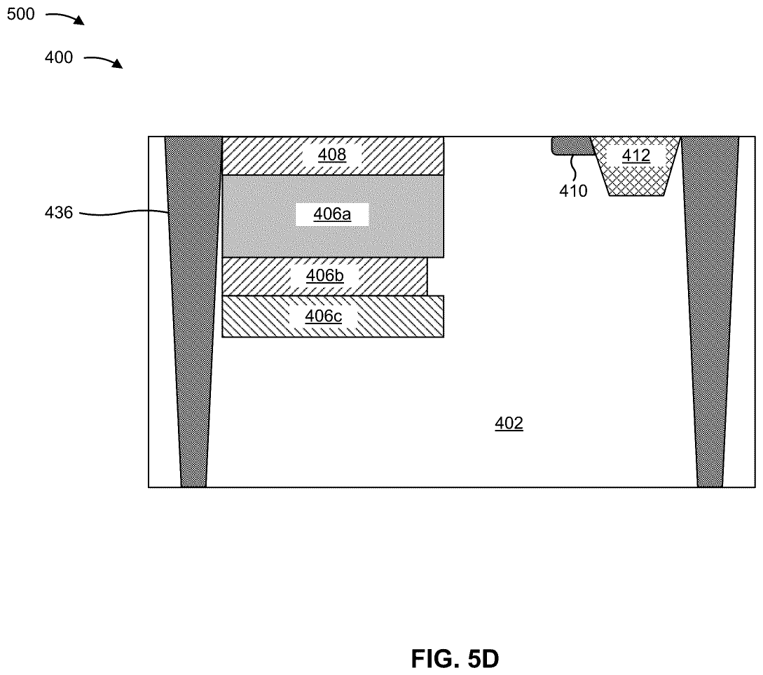

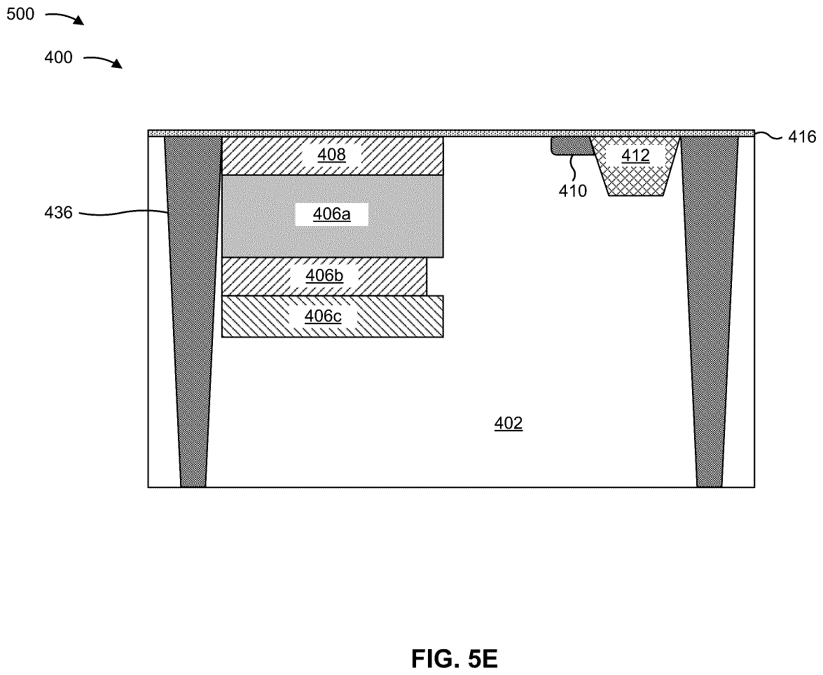

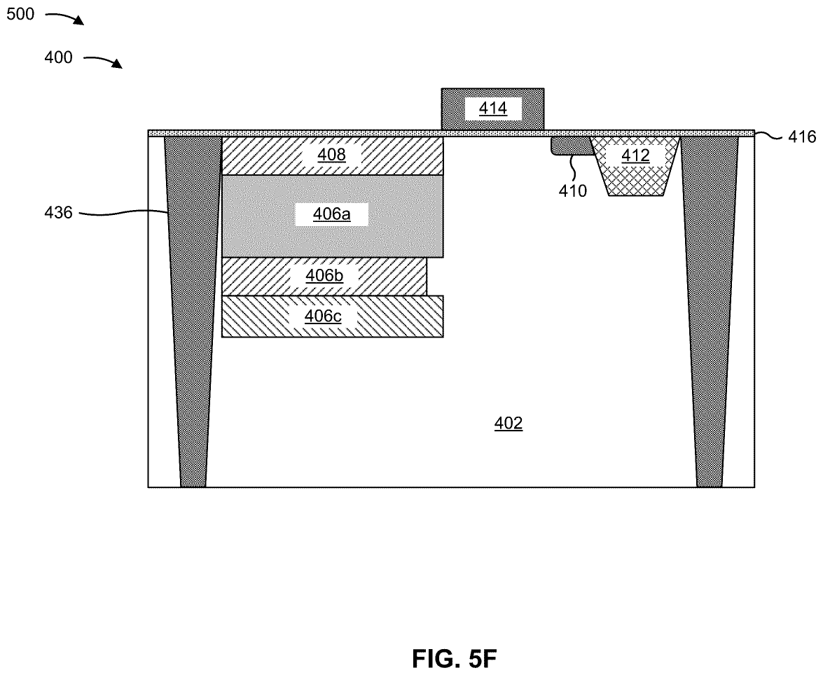

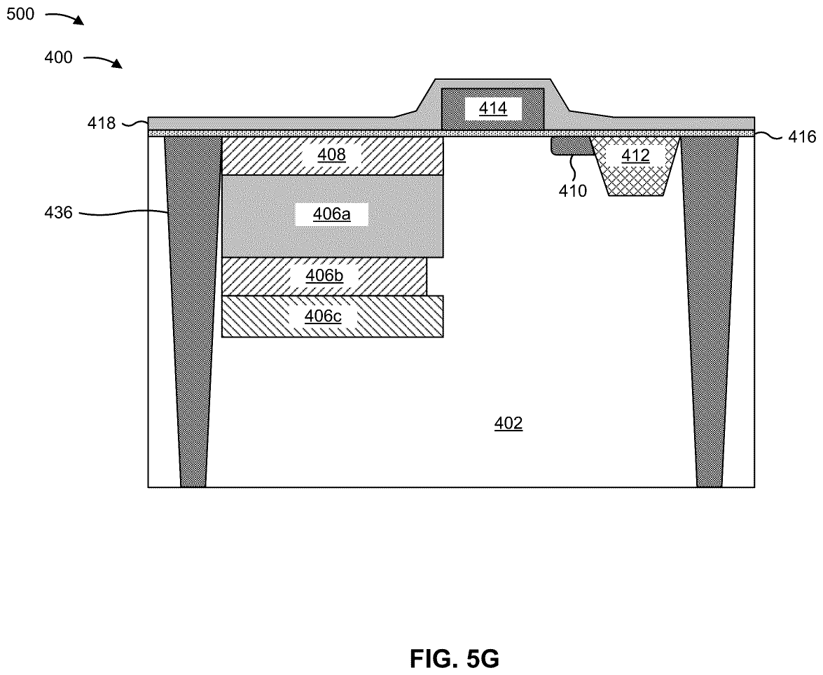

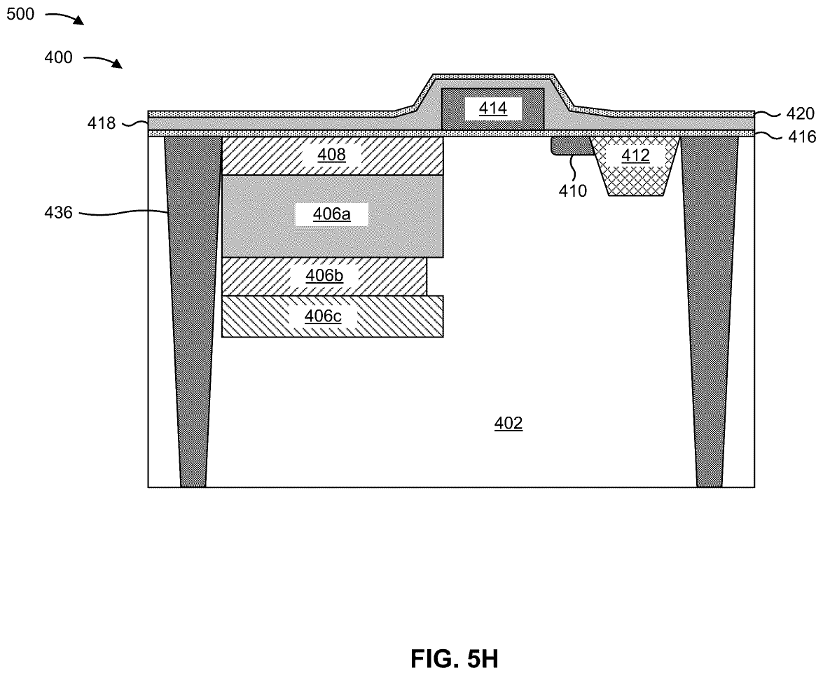

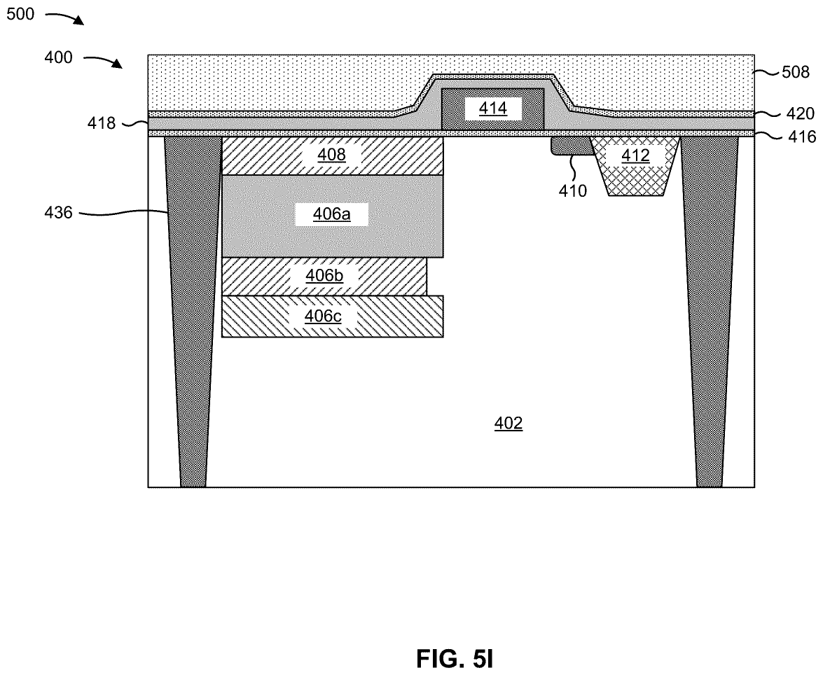

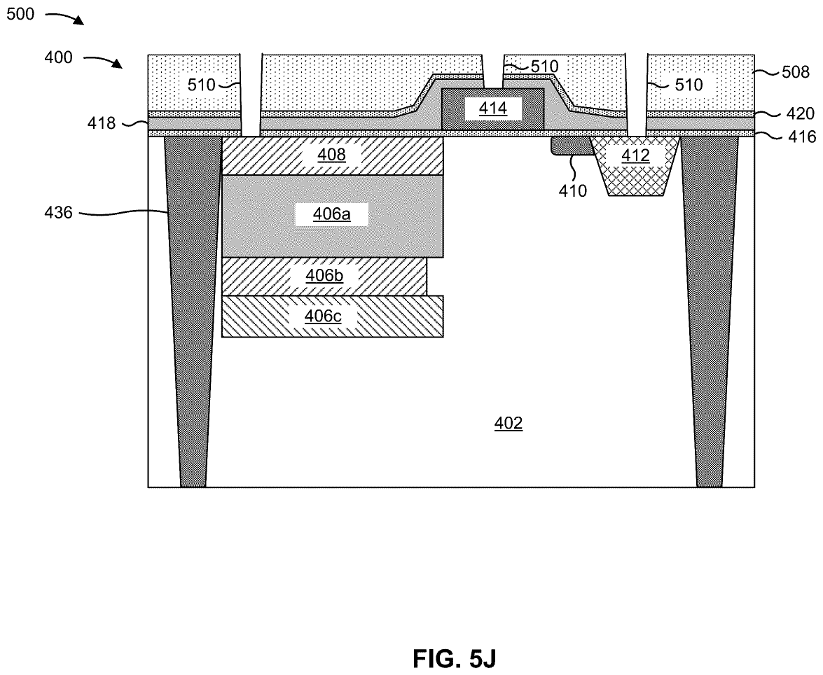

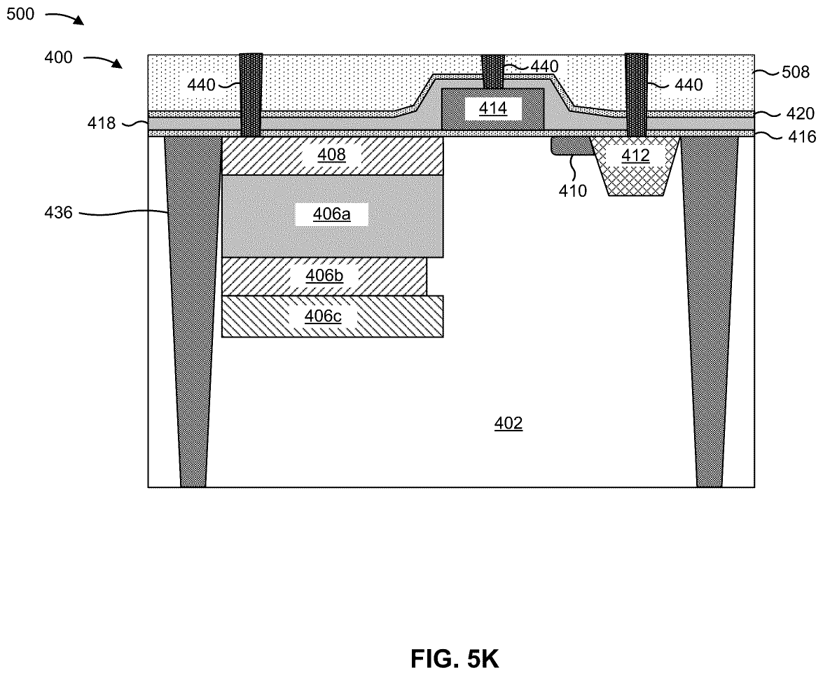

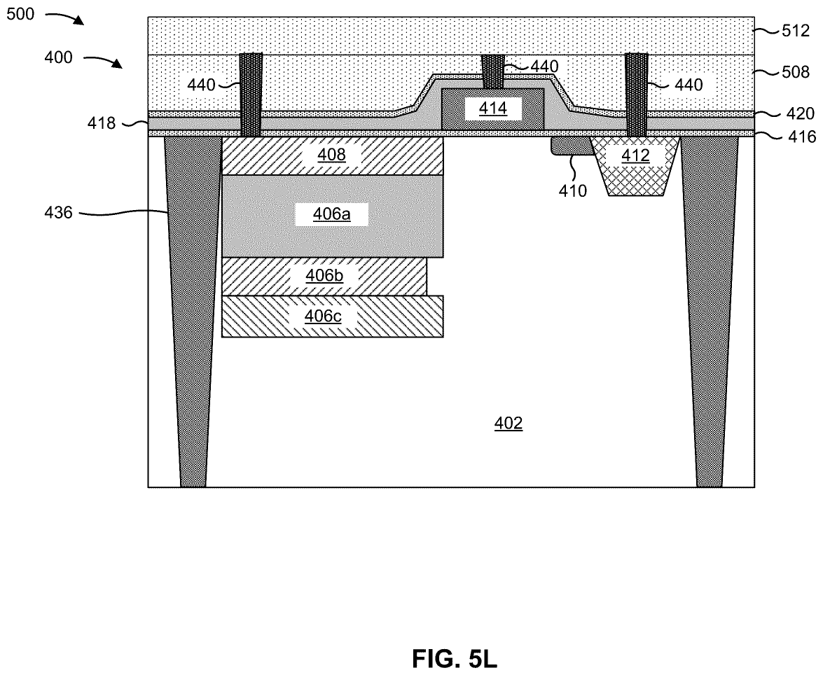

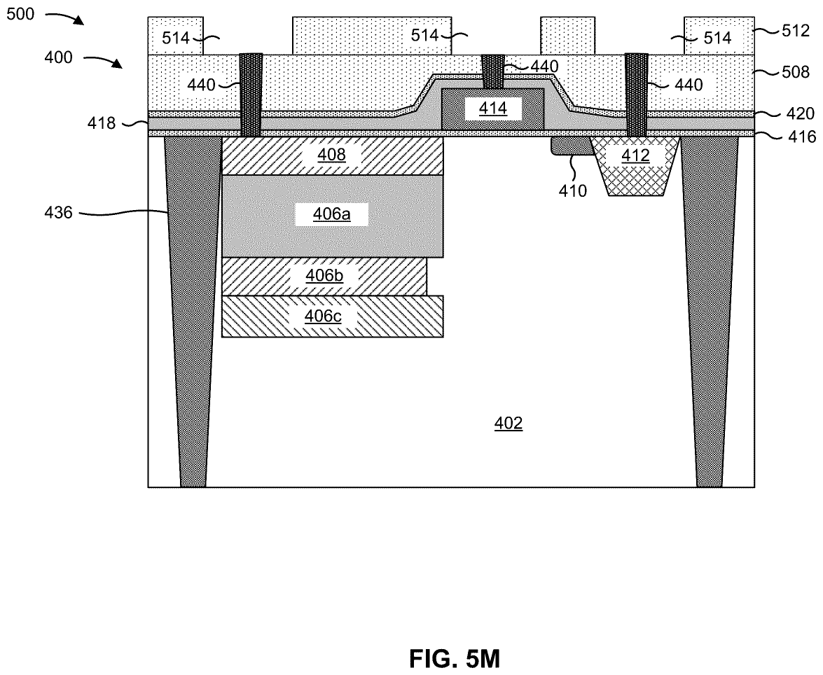

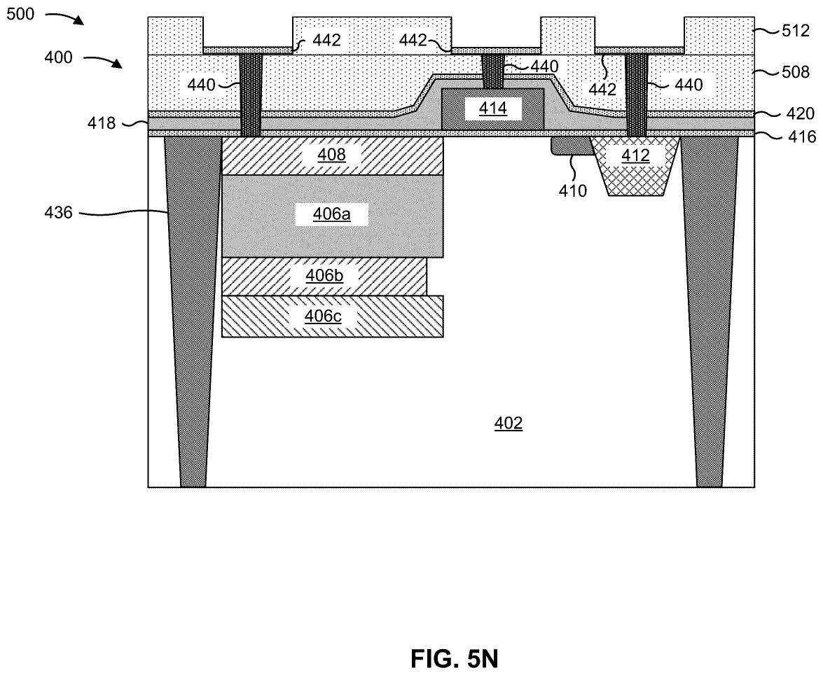

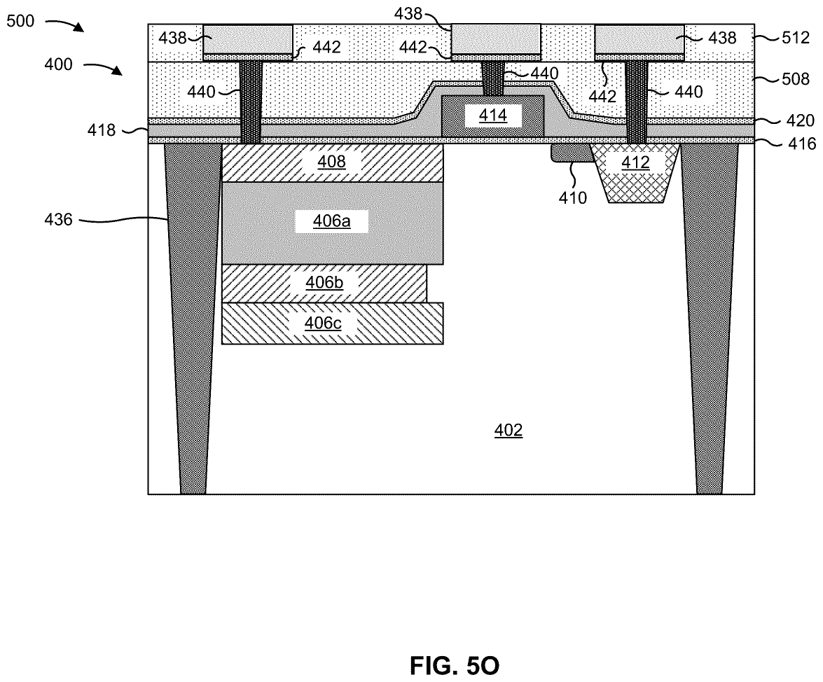

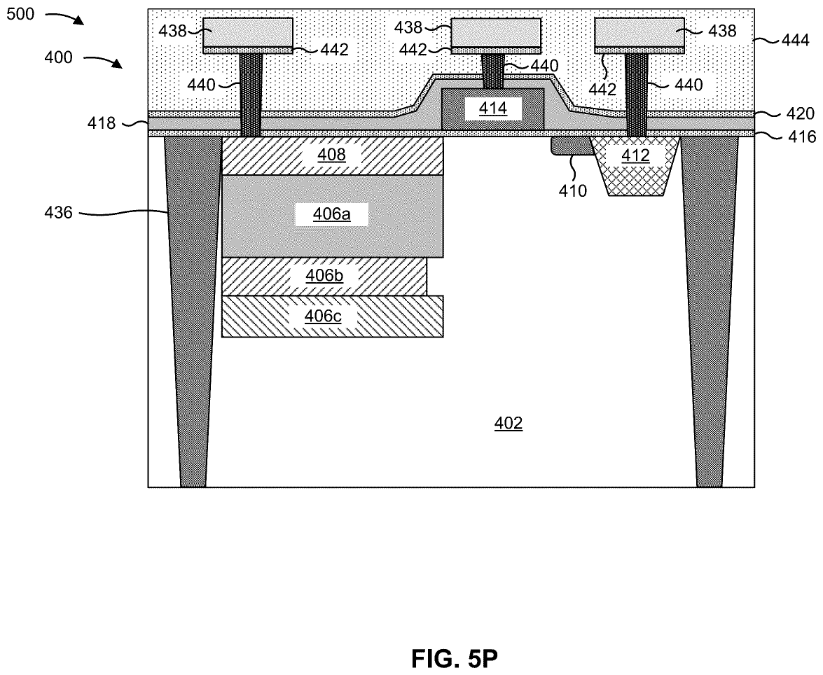

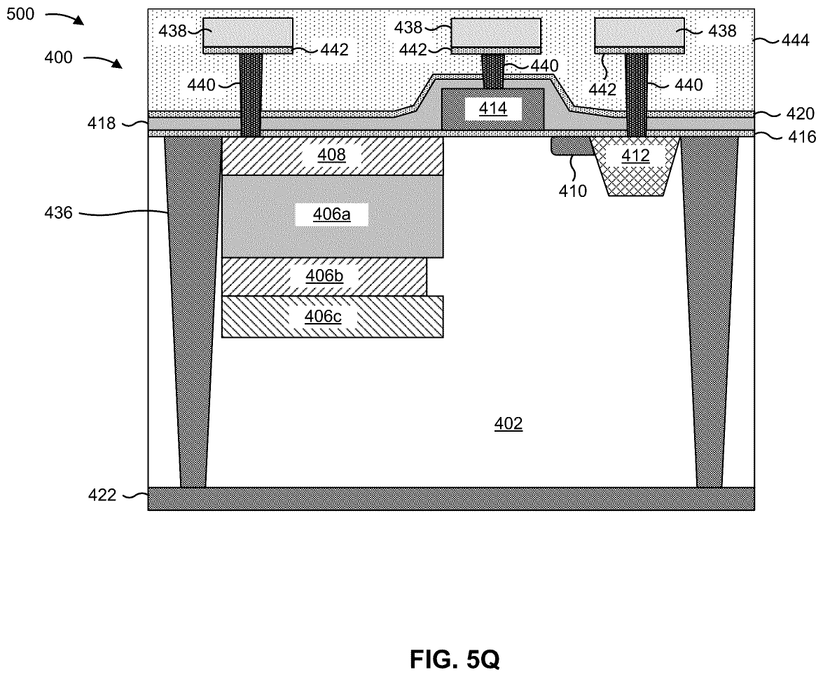

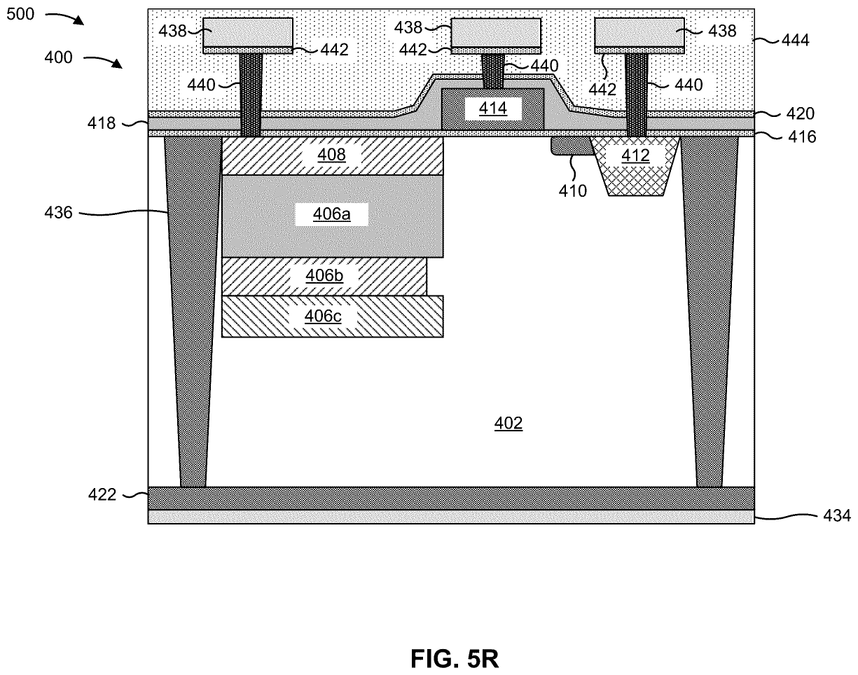

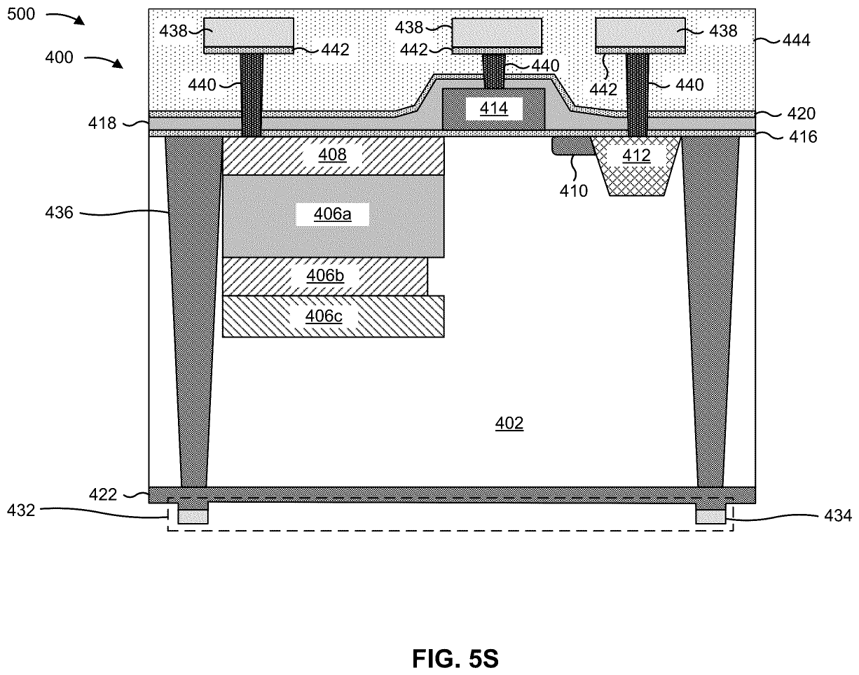

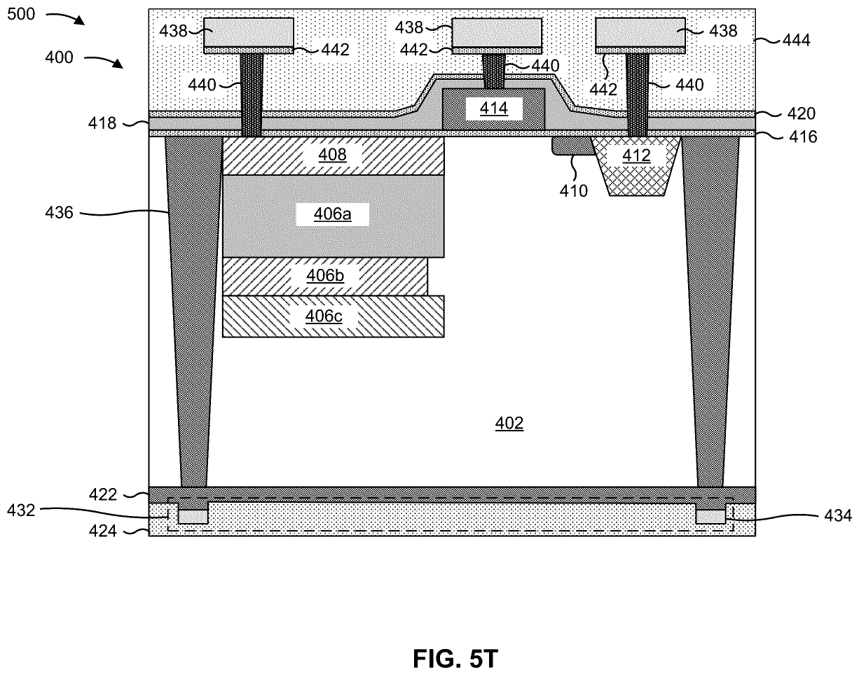

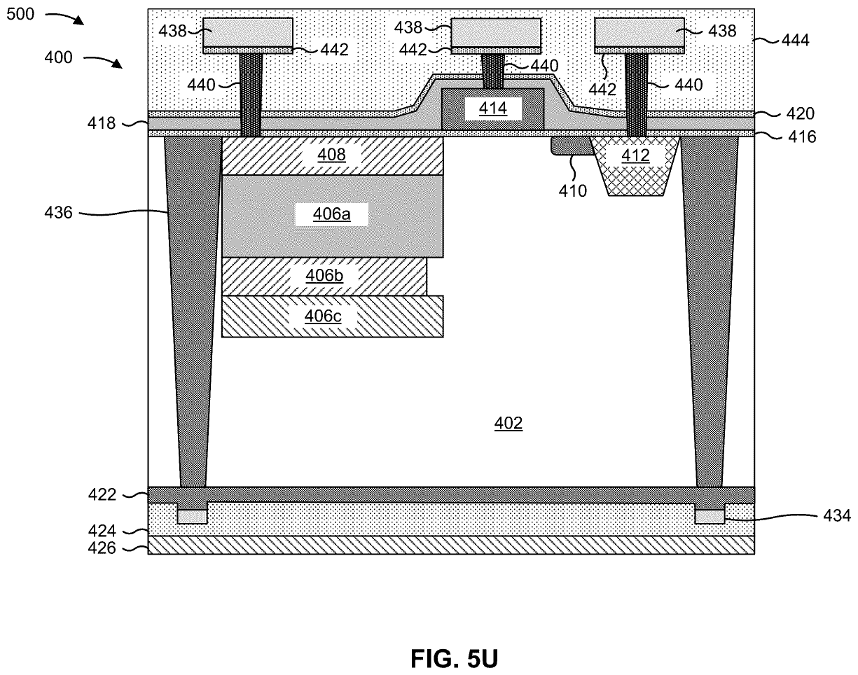

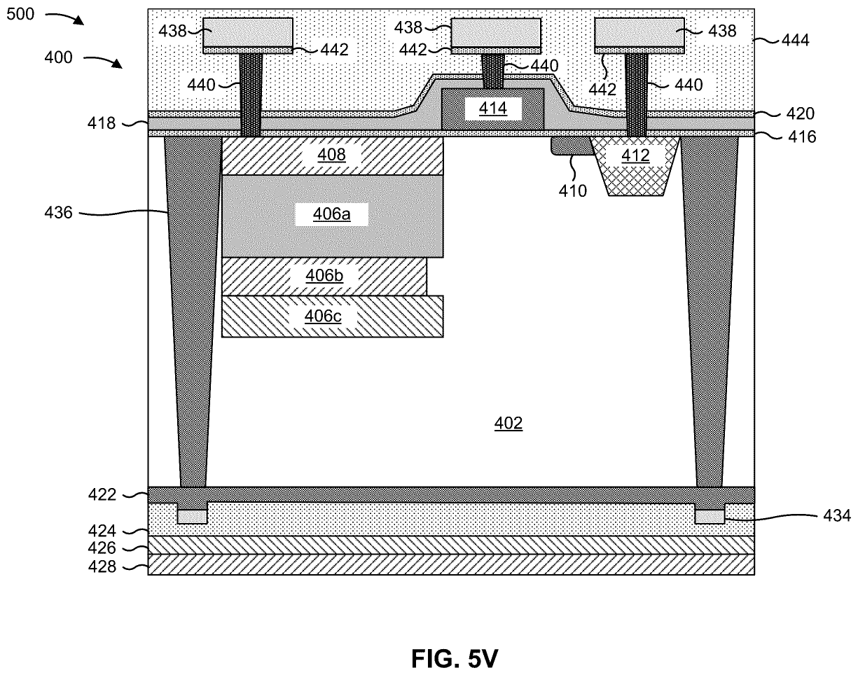

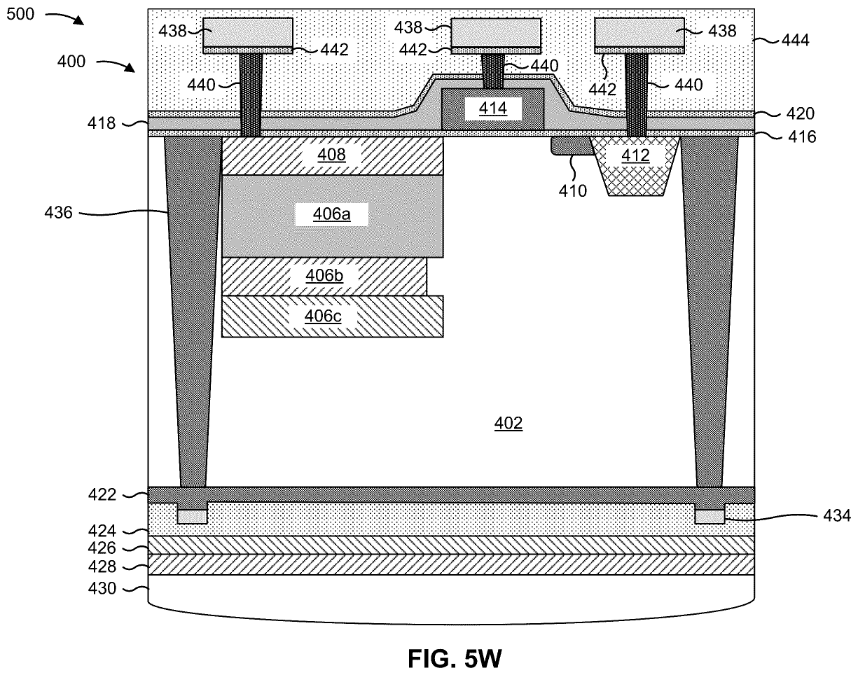

FIGS. 5A-5W are diagrams of an example implementation 500 described herein. Example implementation 500 may be an example process for forming the pixel sensor 400. In some implementations, the example techniques and procedures described in connection with FIGS. 5A-5W may be used to form other pixel sensors described herein or portions thereof. As shown in FIG. 5A, the example process for forming the pixel sensor 400 may be performed in connection with the substrate 402.

As shown in FIG. 5B, a plurality of openings 502 may be formed through the substrate 402 from a first side 504 to a second side 506. The deposition tool 102 may form a photoresist layer on the substrate 402, the exposure tool 104 may expose the photoresist layer to a radiation source to pattern the photoresist layer, the developer tool 106 may develop and remove portions of the photoresist layer to expose the pattern, and the etch tool 108 may etch portions of the substrate 402 to form the openings 502. The etch tool 108 may etch the substrate 402 starting from the first side 504 (e.g., the top surface of the substrate 402), through the substrate 402, and through the second side 506 (e.g., the bottom surface of the substrate 402) such that the openings 502 extend through the substrate 402 on the first side 504 and on the second side 506. Accordingly, the openings 502 may be formed as part of front side processing of the pixel sensor 400, which may result in the width of the openings 502 near the first side 504 being greater relative to the width of the openings 502 near the second side 506. In some implementations, a photoresist removal tool removes the remaining portions of the photoresist layer (e.g., using a chemical stripper, a plasma asher, and/or another technique) after the etch tool 108 etches the substrate 402.

As shown in FIG. 5C, the plurality of openings 502 may be filled with an oxide material to form the DTI structure 436. The deposition tool 102 may deposit the oxide material to form the DTI structure 436 by a CVD technique, a PVD technique, an ALD technique, or another type of deposition technique described above in connection with FIG. 1. The deposition tool 102 may deposit the oxide material from the first side 504 into the openings 502 such that the DTI structure 436 extends through the substrate 402 on the first side 504 and on the second side 506.

As shown in FIG. 5D, a plurality of regions of the substrate 402 may be doped to form the n-type regions 406a-406c, the p-type region 408, the drain extension region 410, and the drain region 412. In some implementations, the ion implantation tool 114 dopes the plurality of regions of the substrate 402 by one or more ion implantation operations. For example, the ion implantation tool 114 may implant n⁺ ions in the substrate 402 to form the n-type regions 406a-406c, may implant p⁺ ions in the substrate 402 to form the p-type region 408, may implant n⁺ ions in the substrate 402 to form the drain extension region 410, and may implant n⁺ ions in the substrate 402 to form the drain region 412. In some implementations, the plurality of regions of the substrate 402 may be doped using another doping technique such as diffusion. In some implementations, the drain region 412 is formed by epitaxial growth.

The ion implantation tool 114 may form the n-type region 406c within the perimeter of the DTI structure 436. The ion implantation tool 114 may form the n-type region 406b above and/or over the n-type region 406c and within the perimeter of the DTI structure 436. The ion implantation tool 114 may form the n-type region 406a above and/or over the n-type region 406b and within the perimeter of the DTI structure 436. The ion implantation tool 114 may form the p-type region 408 above and/or over the n-type region 406a and within the perimeter of the DTI structure 436. The ion implantation tool 114 may form the drain extension region 410 and the drain region 412 within the perimeter of the DTI structure 436. In some implementations, the n-type region 406a, the n-type region 406b, and/or the n-type region 406c may be doped with different n-type dopant concentrations. In some implementations, the drain extension region 410 and the drain region 412 may be doped with different n-type dopant concentrations.

As shown in FIG. 5E, the gate dielectric layer 416 may be formed over and/or on the top surface of the substrate 402. The deposition tool 102 may deposit the gate dielectric layer 416 using a CVD technique, a PVD technique, an ALD technique, or another type of deposition technique described above in connection with FIG. 1. The planarization tool 110 may planarize the gate dielectric layer 416 after the gate dielectric layer 416 is deposited.

As shown in FIG. 5F, the transfer gate 414 may be formed over and/or on the gate dielectric layer 416, and between the regions 406, 408 and the regions 410, 412. In some implementations, the deposition tool 102 deposits the transfer gate 414 using a CVD technique, a PVD technique, an ALD technique, or another type of deposition technique, the plating tool 112 deposits the transfer gate 414 using an electroplating operation, or a combination thereof. In some implementations, the ion implantation tool 114 forms the transfer gate 414 using one or more ion implantation operations.

As shown in FIG. 5G, the oxide layer 418 may be formed over and/or on the gate dielectric layer 416, on the sidewalls of the transfer gate 414, and over and/or on the transfer gate 414. The deposition tool 102 may deposit the oxide layer 418 using a CVD technique, a PVD technique, an ALD technique, or another type of deposition technique described above in connection with FIG. 1.

As shown in FIG. 5H, the contact etch stop layer (CESL) 420 may be formed over and/or on the oxide layer 418 and over the transfer gate 414. The deposition tool 102 may deposit the contact etch stop layer 420 using a CVD technique, a PVD technique, an ALD technique, or another type of deposition technique.

As shown in FIG. 5I, a first layer 508 of the dielectric layer 444 may be formed over and/or on the contact etch stop layer 420. The deposition tool 102 may deposit the first layer 508 using a CVD technique, a PVD technique, an ALD technique, or another type of deposition technique. The planarization tool 110 may planarize the first layer 508 after the first layer 508 is deposited.

As shown in FIG. 5J, a plurality of openings 510 may be formed through the first layer 508. Moreover, one or more of the openings 510 may be formed through the contact etch stop layer 420, through the oxide layer 418, and/or through the gate dielectric layer 416. In some implementations, a first one of the openings 510 may be formed over the p-type region 408; a second one of the openings 510 may be formed over the transfer gate 414; and a third one of the openings 510 may be formed over the drain region 412. The deposition tool 102 may form a photoresist layer on the first layer 508, the exposure tool 104 may expose the photoresist layer to a radiation source to pattern the photoresist layer, the developer tool 106 may develop and remove portions of the photoresist layer to expose the pattern, and the etch tool 108 may etch portions of the first layer 508, the contact etch stop layer 420, the oxide layer 418, and/or the gate dielectric layer 416 to form the openings 510. In some implementations, a photoresist removal tool removes the remaining portions of the photoresist layer (e.g., using a chemical stripper, a plasma asher, and/or another technique).

As shown in FIG. 5K, the openings 510 may be filled to form the interconnect structures 440. The deposition tool 102 may deposit the material of the interconnect structures 440 using a CVD technique, a PVD technique, an ALD technique, or another type of deposition technique, the plating tool 112 may deposit the material of the interconnect structures 440 using an electroplating operation, or a combination thereof. The planarization tool 110 may planarize the interconnect structures 440 after the interconnect structures 440 are deposited.

As shown in FIG. 5L, a second layer 512 of the dielectric layer 444 may be formed over and/or on the first layer 508. The deposition tool 102 may deposit the second layer 512 using a CVD technique, a PVD technique, an ALD technique, or another type of deposition technique. The planarization tool 110 may planarize the second layer 512 after the second layer 512 is deposited.

As shown in FIG. 5M, a plurality of openings 514 may be formed in and/or through the second layer 512 to expose the top surfaces of the interconnect structures 440. In this way, the absorption layer 442 and the conductive structures 438 may be connected to the interconnect structures 440. The deposition tool 102 may form a photoresist layer on the second layer 512, the exposure tool 104 may expose the photoresist layer to a radiation source to pattern the photoresist layer, the developer tool 106 may develop and remove portions of the photoresist layer to expose the pattern, and the etch tool 108 may etch portions of the second layer 512 to form the openings 514. In some implementations, a photoresist removal tool removes the remaining portions of the photoresist layer (e.g., using a chemical stripper, a plasma asher, and/or another technique).

As shown in FIG. 5N, the absorption layer 442 may be formed in the openings 514 and electrically connected to the interconnect structures 440. The deposition tool 102 may deposit the material of the absorption layer 442 using a CVD technique, a PVD technique, an ALD technique, or another type of deposition technique, the plating tool 112 may deposit the material of the absorption layer 442 using an electroplating operation, or a combination thereof.

As shown in FIG. 5O, the conductive structures 438 may be formed in the openings 514 over and/or on the absorption layer 442. The deposition tool 102 may deposit the material of the conductive structures 438 using a CVD technique, a PVD technique, an ALD technique, or another type of deposition technique, the plating tool 112 may deposit the material of the conductive structures 438 using an electroplating operation, or a combination thereof. The planarization tool 110 may planarize the conductive structures 438 after the conductive structures 438 are deposited.

As shown in FIG. 5P, the remaining portion of the dielectric layer 444 may be formed over and/or on the second layer 512. The deposition tool 102 may deposit the remaining portion of the dielectric layer 444 using a CVD technique, a PVD technique, an ALD technique, or another type of deposition technique. The planarization tool 110 may planarize the dielectric layer 444 after the remaining portion of the dielectric layer 444 is deposited.

Back side processing may be performed on the pixel sensor 400. In some implementations, the pixel sensor 400 may be mounted to a carrier substrate so that the back side processing may be performed. As shown in FIG. 5Q, the back side processing may include forming the oxide layer 422 over and/or on the bottom surface of the substrate 402. The deposition tool 102 may deposit the oxide layer 422 using a CVD technique, a PVD technique, an ALD technique, or another type of deposition technique. The planarization tool 110 may planarize the oxide layer 422 after the oxide layer 422 is deposited.

As shown in FIG. 5R, the metal layer 434 may be formed over and/or on the oxide layer 422. The deposition tool 102 may deposit the material of the metal layer 434 using a CVD technique, a PVD technique, an ALD technique, or another type of deposition technique, the plating tool 112 may deposit the material of the metal layer 434 using an electroplating operation, or a combination thereof. The planarization tool 110 may planarize the metal layer 434 after the metal layer 434 is deposited.

As shown in FIG. 5S, portions of the metal layer 434 and portions of the oxide layer 422 may be removed to form the grid structure 432. The grid structure 432 may be formed by coating the metal layer 434 with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching through the metal layer 434 and into a portion of the oxide layer 422 (e.g., using the etch tool 108) based on the pattern in the photoresist.

As shown in FIG. 5T, the dielectric layer 424 may be formed over the back side of the substrate 402 and may fill the spaces in between the grid structure 432. The deposition tool 102 may deposit the dielectric layer 424 using a CVD technique, a PVD technique, an ALD technique, or another type of deposition technique described above in connection with FIG. 1. The dielectric layer 424 may be formed over and/or on the oxide layer 422 and between the interconnected columns of the grid structure 432. The planarization tool 110 may planarize the dielectric layer 424 after the dielectric layer 424 is deposited.

As shown in FIG. 5U, the ARC 426 may be formed over the back side of the substrate 402 and over and/or on the dielectric layer 424. The deposition tool 102 may deposit the ARC 426 using a CVD technique, a PVD technique, an ALD technique, or another type of deposition technique described above in connection with FIG. 1. The planarization tool 110 may planarize the ARC 426 after the ARC 426 is deposited.

As shown in FIG. 5V, the color filter layer 428 may be formed over the back side of the substrate 402 and over and/or on the ARC 426. The deposition tool 102 may deposit the filter layer 428 using a CVD technique, a PVD technique, an ALD technique, or another type of deposition technique described above in connection with FIG. 1. The planarization tool 110 may planarize the filter layer 428 after the filter layer 428 is deposited.

As shown in FIG. 5W, the micro-lens layer 430 may be formed over the back side of the substrate 402 and over and/or on the color filter layer 428. The deposition tool 102 may deposit the micro-lens layer 430 using a CVD technique, a PVD technique, an ALD technique, or another type of deposition technique described above in connection with FIG. 1.

As indicated above, FIGS. 5A-5W are provided as an example. Other examples may differ from what is described with regard to FIGS. 5A-5W.

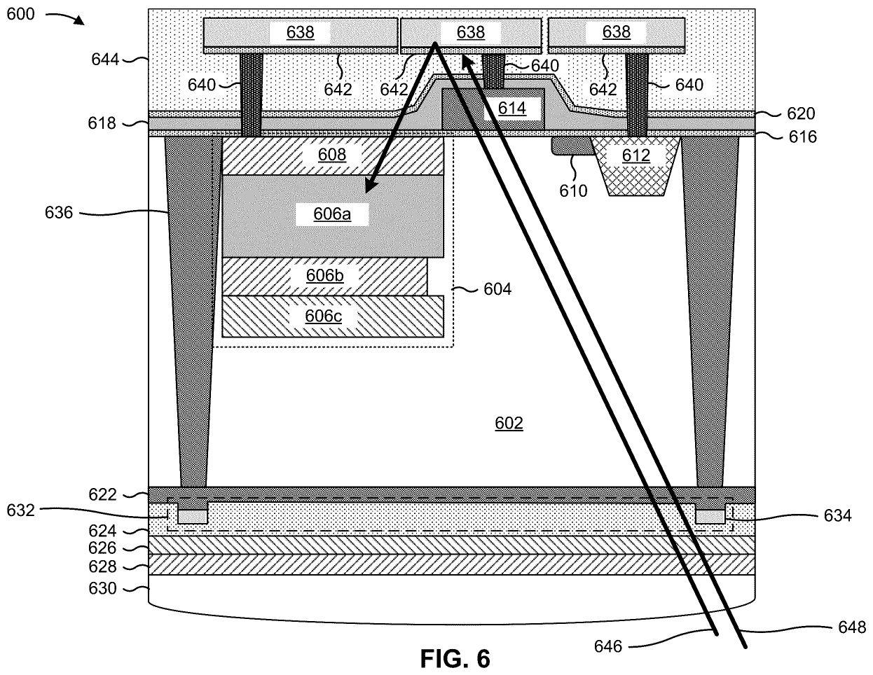

FIG. 6 is a diagram of an example pixel sensor 600 described herein. The pixel sensor 600 may include components 602-644 similar to the components 402-444 of the pixel sensor 400. The pixel sensor 600 may be similar to the pixel sensor 400, except that the pixel sensor 600 includes larger conductive structures 638 that laterally extends further relative to the conductive structures 438. This permits the pixel sensor 600 to reflect a greater amount of the visible light component 646 of incident light into the pixel sensor 600 relative to the pixel sensor 400. Moreover, the pixel sensor 600 includes an absorption layer 642 that laterally extends further relative to the absorption layer 442. This permits the pixel sensor 600 to absorb a greater amount of the infrared light component 648 of incident light into the pixel sensor 600 relative to the pixel sensor 400. The pixel sensor 600 may be formed by the techniques described above in connection with FIGS. 5A-5W.

As indicated above, FIG. 6 is provided as an example. Other examples may differ from what is described with regard to FIG. 6.

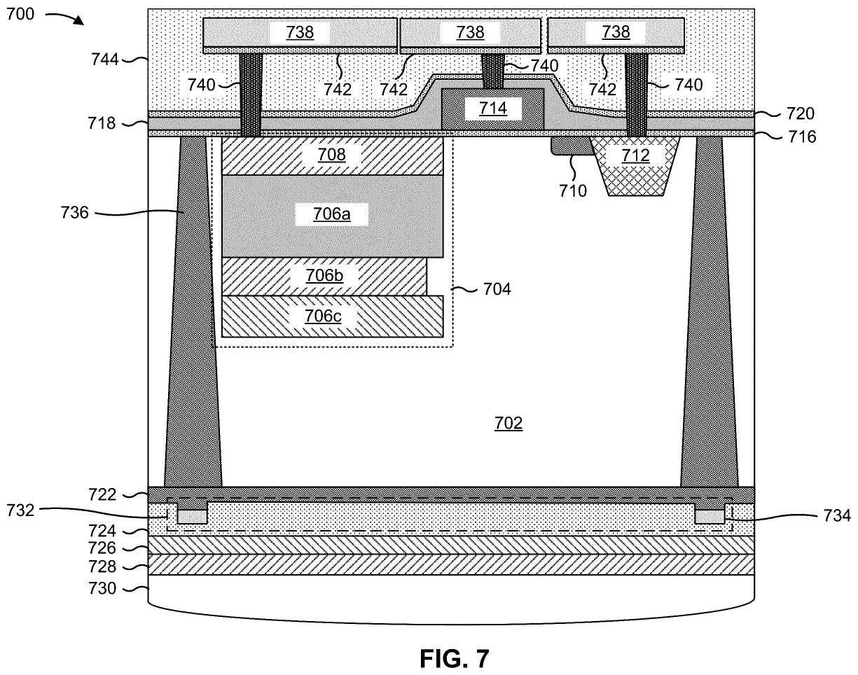

FIG. 7 is a diagram of an example pixel sensor 700 described herein. The pixel sensor 700 may include components 702-744 similar to the components 602-644 of the pixel sensor 600. The pixel sensor 700 may be similar to the pixel sensor 600, except that the DTI structure 736 of the pixel sensor 700 is tapered from the bottom surface of the substrate 702 to the top surface of the substrate 702 such that the width of the DTI structure 736 decreases from the bottom surface of the substrate 702 to the top surface of the substrate 702. This may result from the DTI structure 736 being etched into the back side of the pixel sensor 700 during back side processing of the pixel sensor 700.

As indicated above, FIG. 7 is provided as an example. Other examples may differ from what is described with regard to FIG. 7.

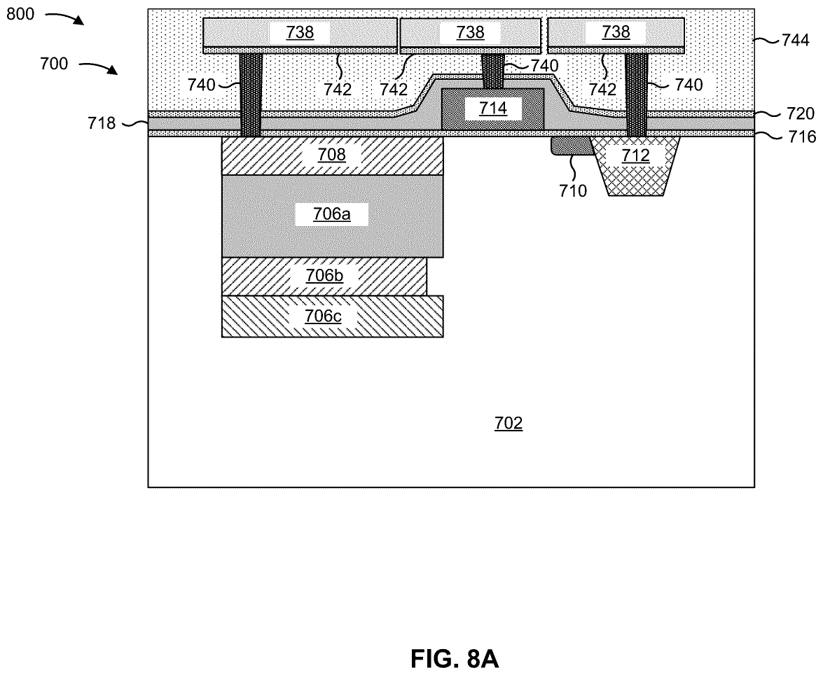

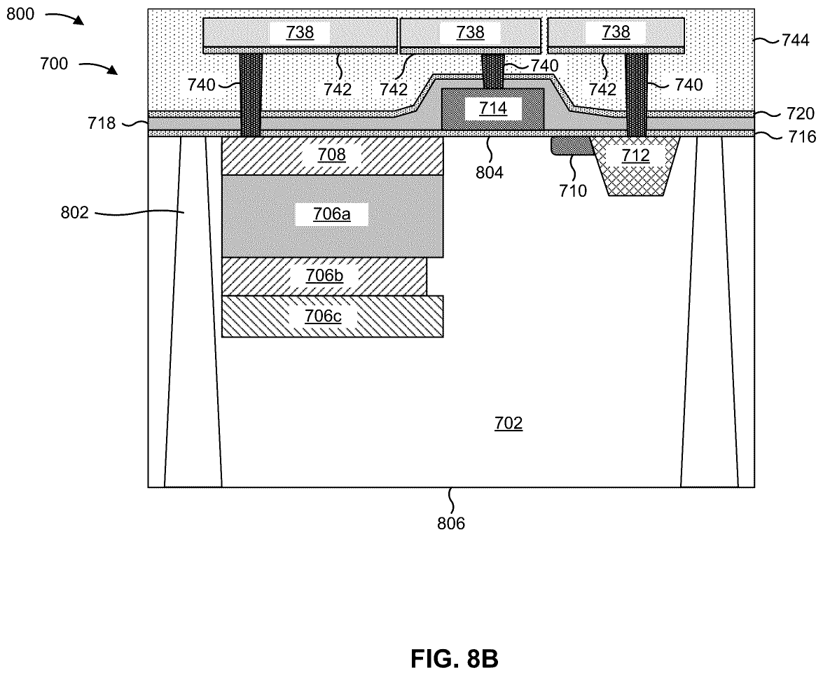

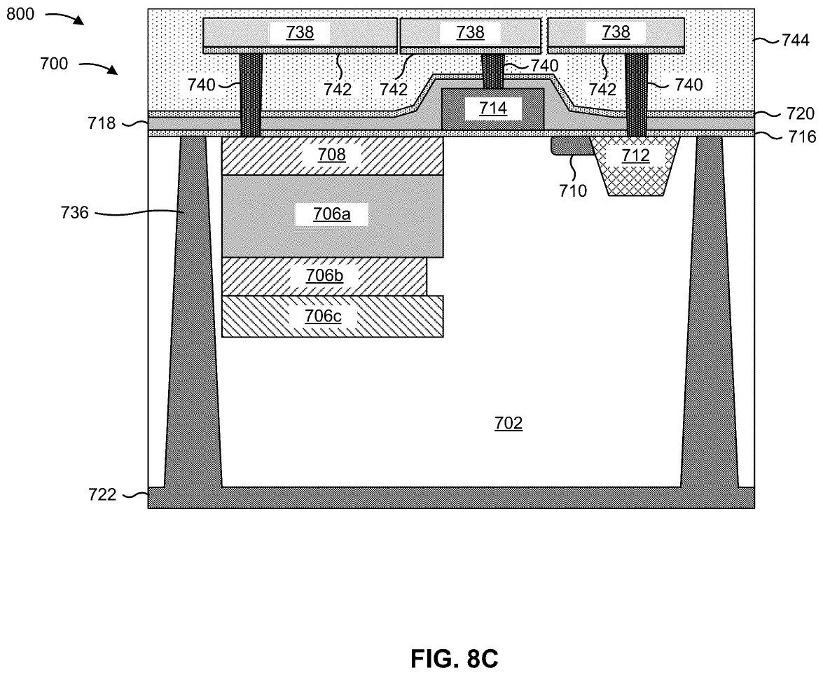

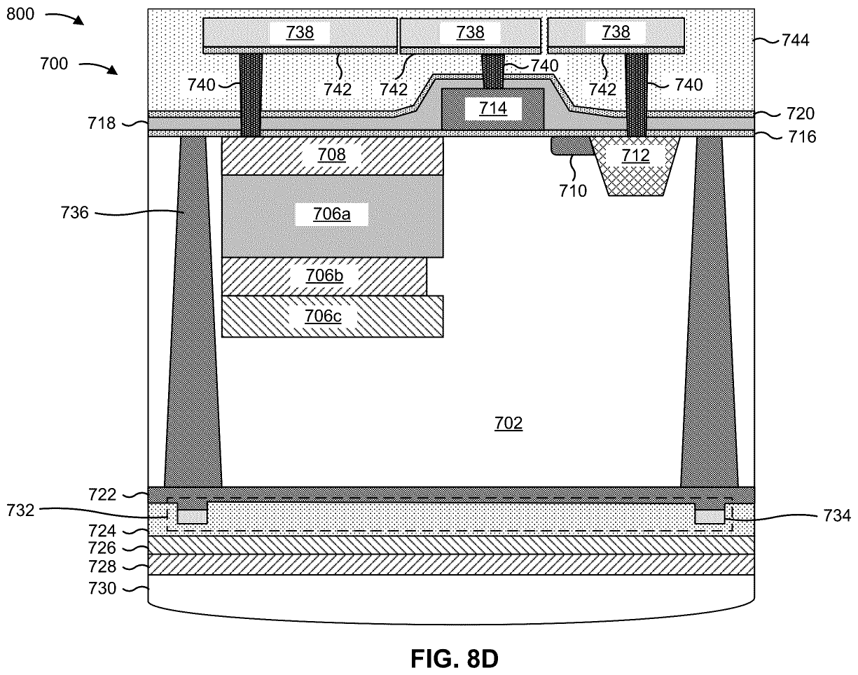

FIGS. 8A-8D are diagrams of an example implementation 800 described herein. Example implementation 800 may be an example process for forming the pixel sensor 700. In some implementations, the example techniques and procedures described in connection with FIGS. 8A-8D may be used in connection with other pixel sensors described herein. As shown in FIG. 8A, the example process for forming the pixel sensor 700 may include one or more of the front side processing operations and/or techniques described above in connection with FIGS. 5A-5P to form a subset of the components and/or structures included in the pixel sensor 700.

As shown in FIG. 8B, a plurality of openings 802 may be formed through the substrate 702 from a second side 806 to a first side 804. The deposition tool 102 may form a photoresist layer on the bottom surface or back side of the substrate 702, the exposure tool 104 may expose the photoresist layer to a radiation source to pattern the photoresist layer, the developer tool 106 may develop and remove portions of the photoresist layer to expose the pattern, and the etch tool 108 may etch portions of the substrate 702 to form the openings 802. The etch tool 108 may etch the substrate 702 starting from the second side 806 (e.g., the bottom surface of the substrate 702), through the substrate 702, and through the first side 804 (e.g., the top surface of the substrate 702) such that the openings 802 extend through the substrate 702 on the first side 804 and on the second side 806. Accordingly, the openings 802 may be formed as part of back side processing of the pixel sensor 700, which may result in the width of the openings 802 near the second side 806 being greater relative to the width of the openings 802 near the first side 804. In some implementations, a photoresist removal tool removes the remaining portions of the photoresist layer (e.g., using a chemical stripper, a plasma asher, and/or another technique) after the etch tool 108 etches the substrate 702.

As shown in FIG. 8C, the plurality of openings 802 may be filled with an oxide material to form the DTI structure 736. The deposition tool 102 may deposit the oxide material to form the DTI structure 736 by a CVD technique, a PVD technique, an ALD technique, or another type of deposition technique described above in connection with FIG. 1. The deposition tool 102 may deposit the oxide material from the second side 806 into the openings 802 such that the DTI structure 736 extends through the substrate 702 on the first side 804 and on the second side 806. The deposition tool 102 may also deposit the oxide material to form the oxide layer 722 over and/or on the back side of the substrate 702 by a CVD technique, a PVD technique, an ALD technique, or another type of deposition technique described above in connection with FIG. 1. The oxide layer 722 may be formed as part of the same deposition operation as the DTI structure 736 or in a separate deposition operation.

As shown in FIG. 8D, the remaining back side processing operations may be performed in a manner similar to the back side processing operations and/or techniques described above in connection with FIGS. 5R-5W to form a subset of the components and/or structures included in the pixel sensor 700.

As indicated above, FIGS. 8A-8D are provided as an example. Other examples may differ from what is described with regard to FIGS. 8A-8D.

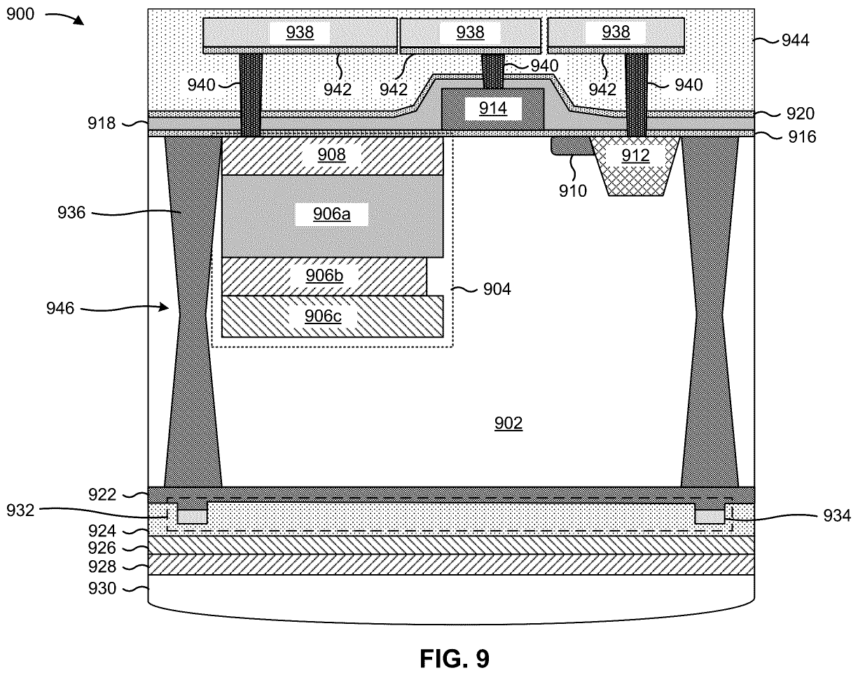

FIG. 9 is a diagram of an example pixel sensor 900 described herein. The pixel sensor 900 may include components 902-944 similar to the components 602-644 of the pixel sensor 600. The pixel sensor 900 may be similar to the pixel sensor 600, except that the DTI structure 936 of the pixel sensor 900 is tapered inward in the substrate 902 from both the bottom surface of the substrate 902 and from the top surface of the substrate 902 such that the DTI structure 936 includes a concave shape (or an hourglass shape). The width of the DTI structure 936 may decrease from the bottom surface of the substrate 902 and from the top surface of the substrate 902 toward an intermediate point 946 (e.g., a center point or another location) along the height of the DTI structure 936 in the substrate 902. This concave shape may result from the DTI structure 936 being formed by multiple operations as part of front side processing and back side processing of the pixel sensor 900.

As indicated above, FIG. 9 is provided as an example. Other examples may differ from what is described with regard to FIG. 9.

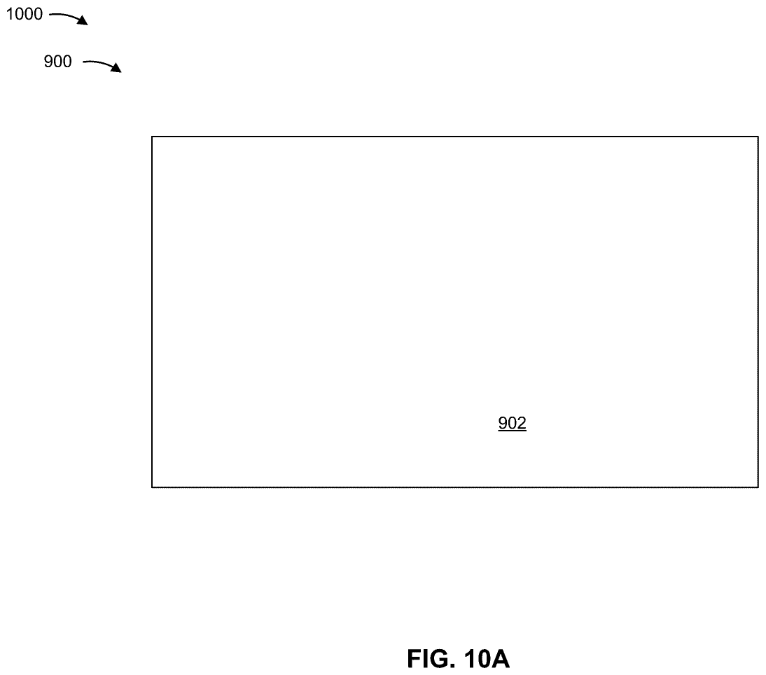

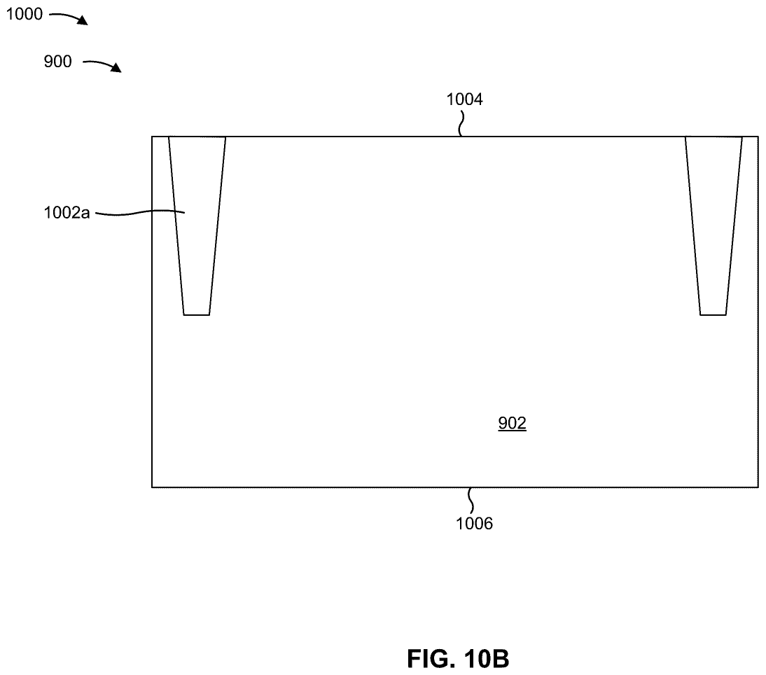

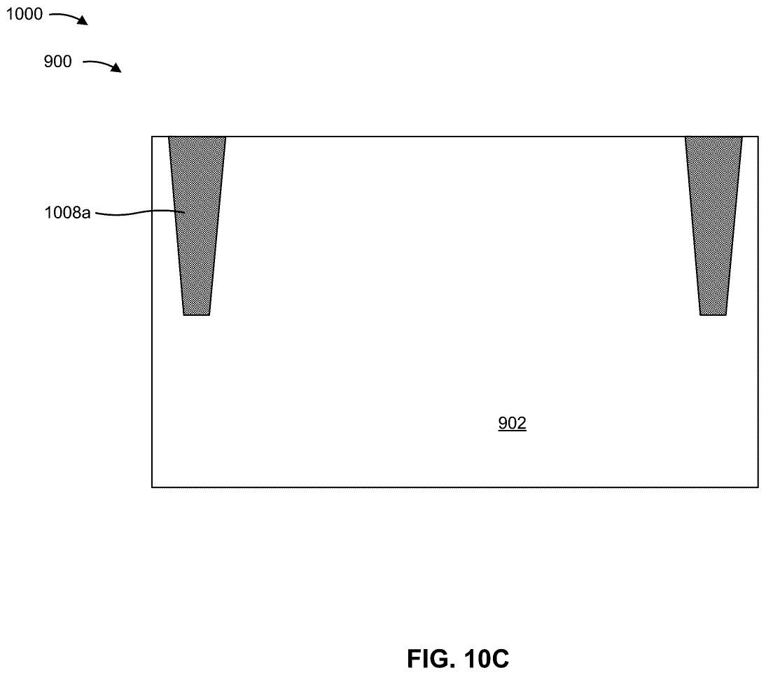

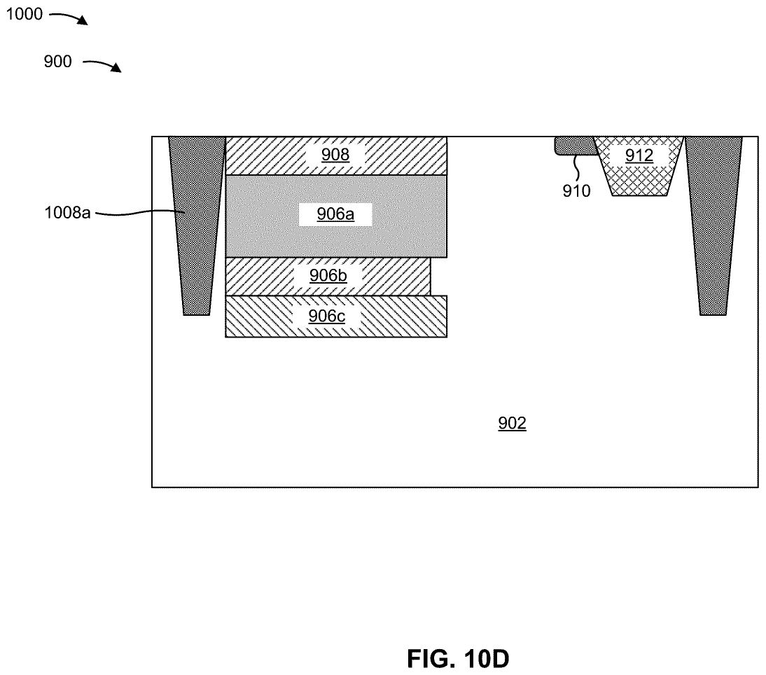

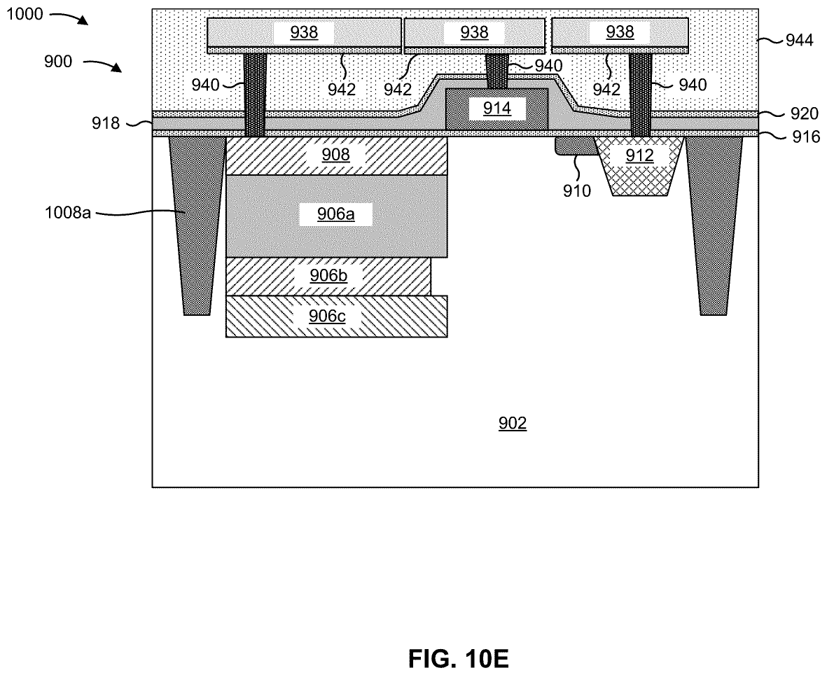

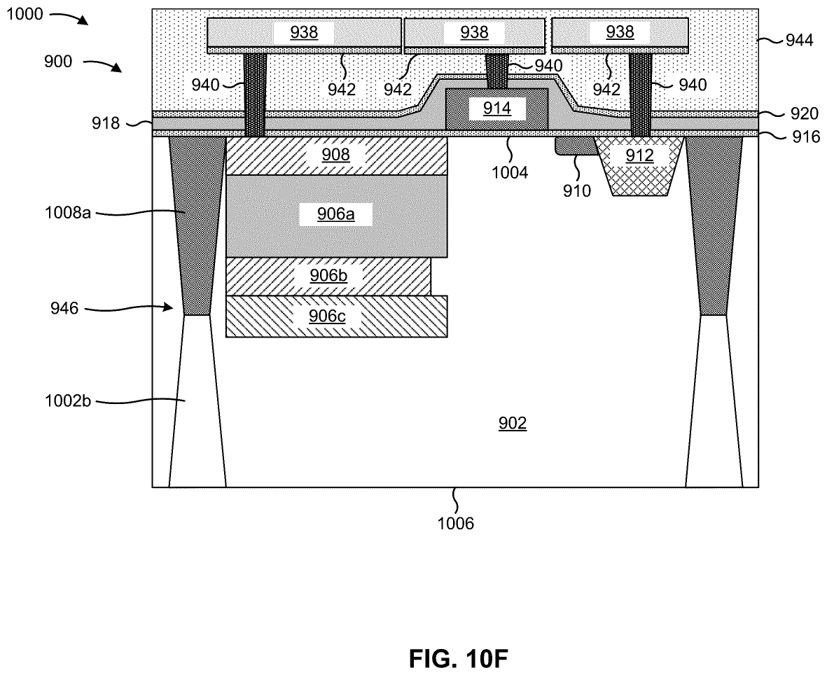

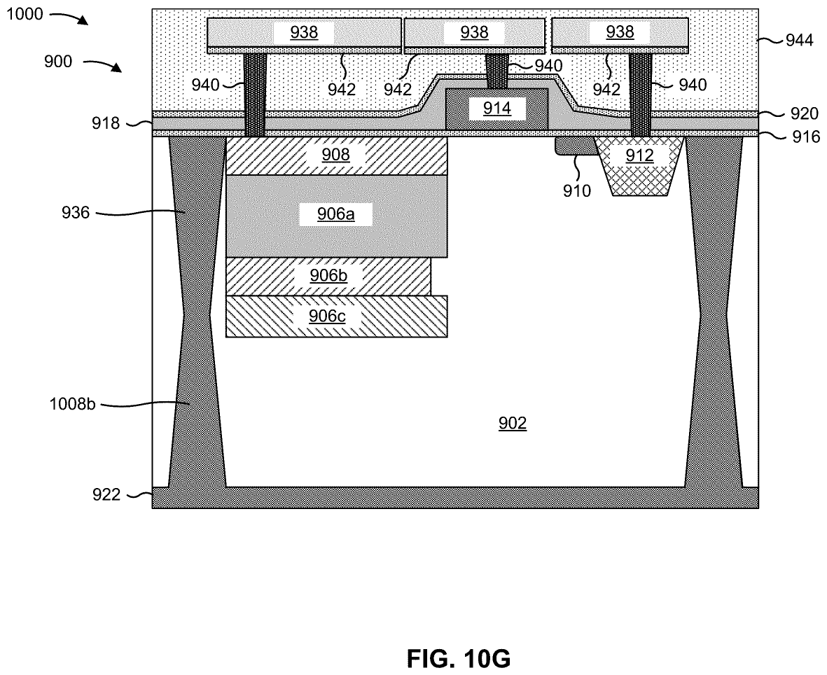

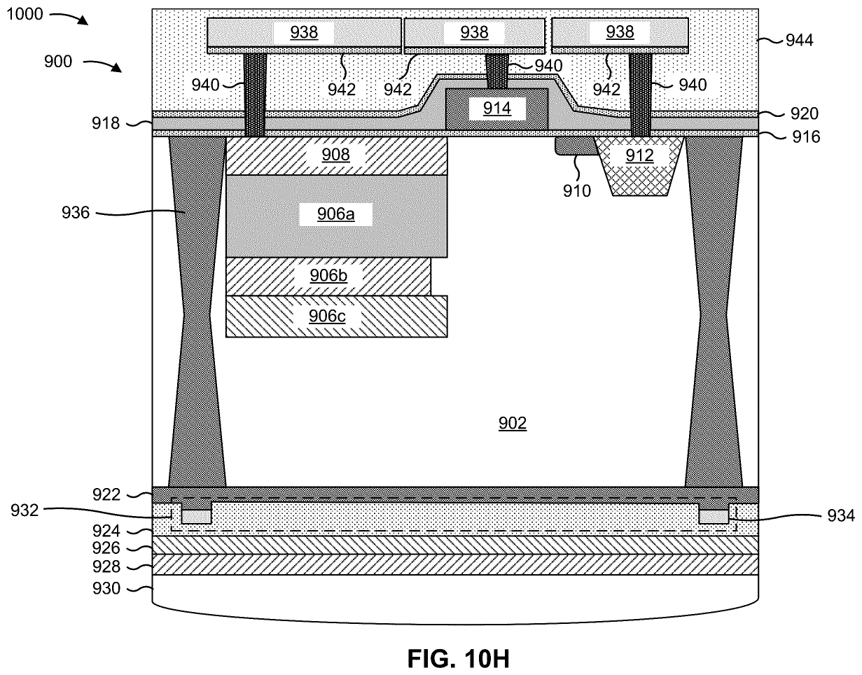

FIGS. 10A-10H are diagrams of an example implementation 1000 described herein. Example implementation 1000 may be an example process for forming the pixel sensor 900. In some implementations, the example techniques and procedures described in connection with FIGS. 10A-10H may be used to form other pixel sensors described herein or portions thereof. As shown in FIG. 10A, the example process for forming the pixel sensor 900 may be performed in connection with the substrate 902.

As shown in FIG. 10B, a first portion 1002a of a plurality of openings 1002 may be formed into a portion of the substrate 902 from a first side 1004 toward a second side 1006. The deposition tool 102 may form a photoresist layer on the substrate 902, the exposure tool 104 may expose the photoresist layer to a radiation source to pattern the photoresist layer, the developer tool 106 may develop and remove portions of the photoresist layer to expose the pattern, and the etch tool 108 may etch portions of the substrate 902 to form the first portion 1002a of the openings 1002. The etch tool 108 may etch the substrate 902 starting from the first side 1004 (e.g., the top surface of the substrate 902) and into the substrate 902 toward the second side 1006 (e.g., the bottom surface of the substrate 902) such that the first portion 1002a of the openings 1002 extends into the substrate 902 from the first side 1004. Accordingly, the first portion 1002a of the openings 1002 may be formed as part of front side processing of the pixel sensor 900, which may result in the width of the first portion 1002a of the openings 1002 near the first side 1004 being greater relative to the width of the first portion 1002a of the openings 1002 near the bottom of the first portion 1002a of the openings 1002. In some implementations, a photoresist removal tool removes the remaining portions of the photoresist layer (e.g., using a chemical stripper, a plasma asher, and/or another technique) after the etch tool 108 etches the substrate 902.

As shown in FIG. 10C, the first portion 1002a of the openings 1002 may be filled with an oxide material to form a first portion 1008a of the DTI structure 936. The deposition tool 102 may deposit the oxide material to form the first portion 1008a of the DTI structure 936 by a CVD technique, a PVD technique, an ALD technique, or another type of deposition technique described above in connection with FIG. 1. The deposition tool 102 may deposit the oxide material from the first side 1004 into the first portion 1002a of the openings 1002 such that the first portion 1008a of the DTI structure 936 extends into the substrate 902 from the first side 1004.

As shown in FIG. 10D, a plurality of regions of the substrate 902 may be doped to form the n-type regions 906a-906c, the p-type region 908, the drain extension region 910, and the drain region 912 in a similar manner as described above in connection with FIG. 5D. As shown in FIG. 10E, additional front side processing techniques and/or operations may be performed to form a subset of the structures and/or components of the pixel sensor 900 in a similar manner as described above in connection with FIGS. 5E-5P.

As shown in FIG. 10F, a second portion 1002b of a plurality of openings 1002 may be formed into another portion of the substrate 902 from the second side 1006 toward the first side 1004. The deposition tool 102 may form a photoresist layer on the substrate 902, the exposure tool 104 may expose the photoresist layer to a radiation source to pattern the photoresist layer, the developer tool 106 may develop and remove portions of the photoresist layer to expose the pattern, and the etch tool 108 may etch portions of the substrate 902 to form the second portion 1002b of the openings 1002. The etch tool 108 may etch the substrate 902 starting from the second side 1006 (e.g., the bottom surface of the substrate 902) and into the substrate 902 toward the first side 1004 (e.g., the top surface of the substrate 902) such that the second portion 1002b of the openings 1002 extends into the substrate 902 from the second side 1006. Accordingly, the second portion 1002b of the openings 1002 may be formed as part of back side processing of the pixel sensor 900, which may result in the width of the second portion 1002b of the openings 1002 near the second side 1006 being greater relative to the width of the second portion 1002b of the openings 1002 near the bottom of the first portion 1002b of the openings 1002 (e.g., near the intermediate point 946). The etch tool 108 may etch the second portion 1002b of the openings 1002 such that the second portion 1002b connects with the first portion 1002a at the intermediate point 946 (e.g., a center point or another location) along the height of the DTI structure 936 in the substrate 902. In some implementations, a photoresist removal tool removes the remaining portions of the photoresist layer (e.g., using a chemical stripper, a plasma asher, and/or another technique) after the etch tool 108 etches the substrate 902.

As shown in FIG. 10G, the second portion 1002b of the openings 1002 may be filled with an oxide material to form a second portion 1008b of the DTI structure 936 that connects with the first portion 1008a of the DTI structure 936. This forms a continuous DTI structure 936 in the substrate 902 extending between and to the first side 1004 and the second side 1006. The deposition tool 102 may deposit the oxide material to form the second portion 1008b of the DTI structure 936 by a CVD technique, a PVD technique, an ALD technique, or another type of deposition technique described above in connection with FIG. 1. The deposition tool 102 may deposit the oxide material from the second side 1006 into the second portion 1002b of the openings 1002 such that the second portion 1008b of the DTI structure 936 extends into the substrate 902 from the second side 1006. The oxide material of the first portion 1008a may be the same oxide material as the second portion 1008b or a different oxide material.

As further shown in FIG. 10G, the deposition tool 102 may also deposit the oxide material to form the oxide layer 922 over and/or on the back side of the substrate 902 by a CVD technique, a PVD technique, an ALD technique, or another type of deposition technique described above in connection with FIG. 1. The oxide layer 922 may be formed as part of the same deposition operation as the second portion 1008b of the DTI structure 936 or in a separate deposition operation.

As shown in FIG. 10H, the remaining back side processing operations may be performed in a manner similar to the back side processing operations and/or techniques described above in connection with FIGS. 5R-5W to form a subset of the components and/or structures included in the pixel sensor 900.

As indicated above, FIGS. 10A-10H are provided as an example. Other examples may differ from what is described with regard to FIGS. 10A-10H.

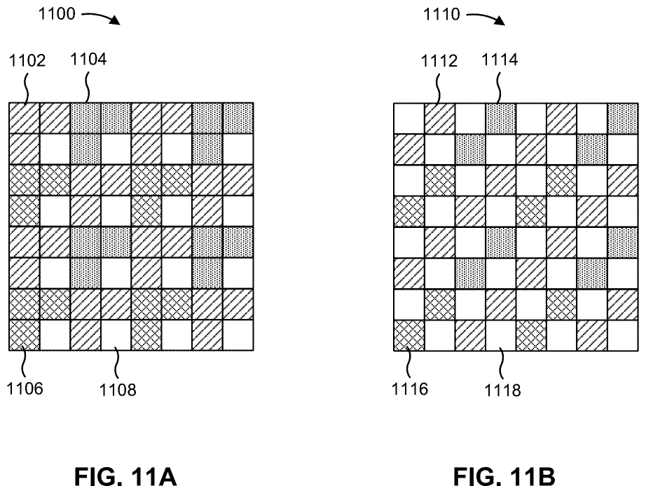

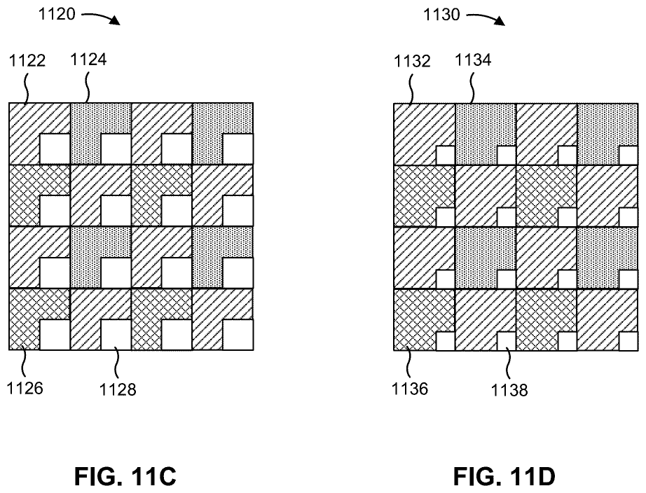

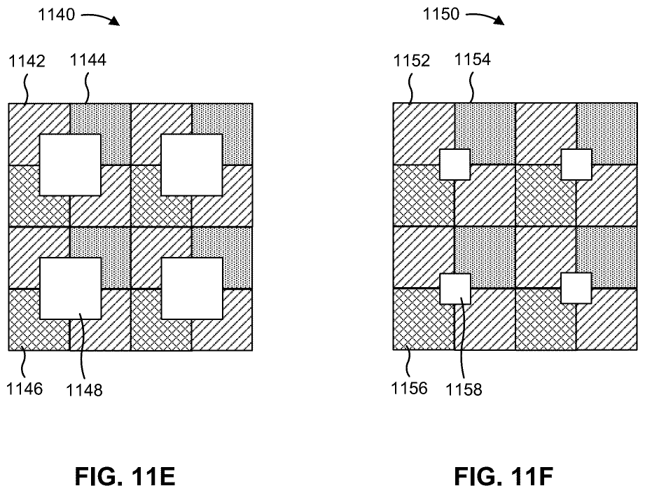

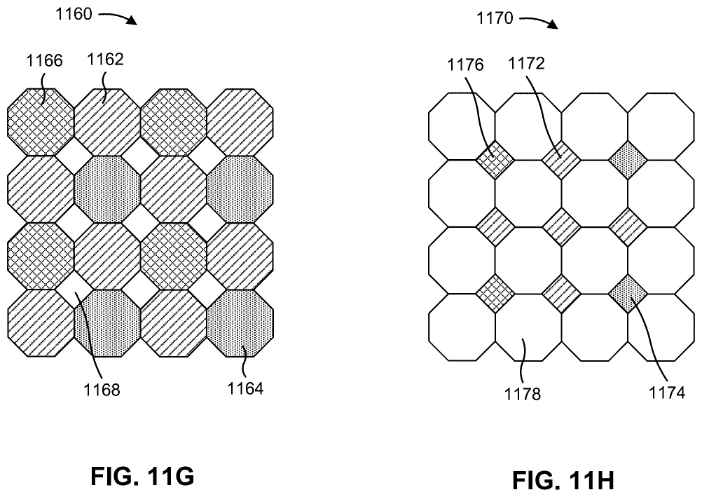

FIGS. 11A-11H are diagrams of example pixel sensor configurations described herein. The example pixel sensor configurations may include example pixel sensor configurations of visible light pixel sensors and white sensors for the pixel array 200 and/or 300 described herein. The pixel sensors included in the example pixel sensor configurations described in connection with FIGS. 11A-11H may include a pixel sensor 202, an octagon-shaped pixel sensor 302, a square-shaped pixel sensor 304, and/or one or more of the pixel sensors 400, 600, 700, and/or 900. Moreover, the pixel sensors included in the example pixel sensor configurations described in connection with FIGS. 11A-11H may be electrically and optically isolated by a DTI structure such as the DTI structure 204, 306, 436, 636, 736, and/or 936.

As shown in FIG. 11A, an example pixel sensor configuration 1100 may include a plurality of pixel sensors arranged in a grid. The pixel sensors may include a subset of green pixel sensors 1102 (e.g., pixel sensors configured to generate green light information), a subset of blue pixel sensors 1104 (e.g., pixel sensors configured to generate blue light information), a subset of red pixel sensors 1106 (e.g., pixel sensors configurated to generate red light information), and a subset of white pixel sensors 1108 (e.g., pixel sensors configured to generate luminance information).

The pixel sensors included in the pixel sensor configuration 1100 may be arranged in groups of contiguous pixel sensors of the same color types along with a white pixel sensor 1108. For example, the pixel sensor configuration 1100 may include one or more groups of a plurality of contiguous green pixel sensors 1102, each arranged with an associated white pixel sensor 1108. The pixel sensor configuration 1100 may include one or more groups of a plurality of contiguous blue pixel sensors 1104, each arranged with an associated white pixel sensor 1108. The pixel sensor configuration 1100 may include one or more groups of a plurality of contiguous red pixel sensors 1106, each arranged with an associated white pixel sensor 1108. Arranging groups of contiguous pixel sensors of the same color types may provide increased optical crosstalk performance, as there is less opportunity for incident light that is filtered for a first color (e.g., green) to travel into a pixel sensor of another color type (e.g., red) because there are fewer adjacent pixel sensors of different color types.

As shown in FIG. 11B, an example pixel sensor configuration 1110 may include green pixel sensors 1112, blue pixel sensors 1114, red pixel sensors 1116, and white pixel sensors 1118. The example pixel sensor configuration 1110 may be similar to the example pixel sensor configuration 1100, except that the example pixel sensor configuration 1110 includes a greater ratio of white pixel sensors 1118 to visible light pixel sensors (e.g., green pixel sensors 1112, blue pixel sensors 1114, and red pixel sensors 1116). In some implementations, the ratio between white pixel sensors 1118 and visible light pixel sensors is 1:1. This configuration may provide increased luminance sensitivity and low-light performance while still providing sufficient color sensitivity.

As shown in FIG. 11C, an example pixel sensor configuration 1120 may include green pixel sensors 1122, blue pixel sensors 1124, red pixel sensors 1126, and white pixel sensors 1128. The example pixel sensor configuration 1120 may include physically larger green pixel sensors, blue pixel sensors, and red pixel sensors relative to the example pixel sensor configuration 1100 and the example pixel sensor configuration 1110. Moreover, the green pixel sensors 1122, the blue pixel sensors 1124, and the red pixel sensors 1126 may be physically larger relative to the white pixel sensors 1128. The green pixel sensors 1122, the blue pixel sensors 1124, and the red pixel sensors 1126 may be configured as approximately square-shaped, except that the white pixel sensors 1128 are arranged near a corner of the green pixel sensors 1122, the blue pixel sensors 1124, and the red pixel sensors 1126. The larger pixel sensors of the example pixel sensor configuration 1120 may provide a larger area over which the pixel sensors can absorb incident light. However, the larger pixel sensors include fewer pixel sensors relative to the example pixel sensor configuration 1100 and the example pixel sensor configuration 1110 and/or may result in the pixel sensor configuration 1120 being physically larger relative to the example pixel sensor configuration 1100 and the example pixel sensor configuration 1110.

As shown in FIG. 11D, an example pixel sensor configuration 1130 may include green pixel sensors 1132, blue pixel sensors 1134, red pixel sensors 1136, and white pixel sensors 1138. The example pixel sensor configuration 1130 may be similar to the example pixel sensor configuration 1120, except that the example pixel sensor configuration 1130 includes physically smaller white pixel sensors 1138 relative to the white pixel sensors 1128. This configuration may provide increased color sensitivity while still providing sufficient luminance sensitivity and low-light performance.

As shown in FIG. 11E, an example pixel sensor configuration 1140 may include green pixel sensors 1142, blue pixel sensors 1144, red pixel sensors 1146, and white pixel sensors 1148. The example pixel sensor configuration 1140 may be similar to the example pixel sensor configuration 1130, except that the example pixel sensor configuration 1140 includes physically larger white pixel sensors 1148 relative to the white pixel sensors 1138 and fewer white pixel sensors 1148 relative to the white pixel sensors 1138. The white pixel sensors 1148 are shared among the visible light pixel sensors. The larger white pixel sensors 1148 may be less complex to manufacture relative to the greater quantity of smaller pixel sensors 1138 while still providing sufficient luminance sensitivity and low-light performance.

As shown in FIG. 11F, an example pixel sensor configuration 1150 may include green pixel sensors 1152, blue pixel sensors 1154, red pixel sensors 1156, and white pixel sensors 1158. The example pixel sensor configuration 1150 may be similar to the example pixel sensor configuration 1140, except that the example pixel sensor configuration 1150 includes physically smaller white pixel sensors 1158 relative to the white pixel sensors 1148. This configuration may provide increased color sensitivity while still providing sufficient luminance sensitivity and low-light performance.

As shown in FIG. 11G, an example pixel sensor configuration 1160 may include green pixel sensors 1162, blue pixel sensors 1164, red pixel sensors 1166, and white pixel sensors 1168. The example pixel sensor configuration 1160 includes octagon-shaped pixel sensors and square-shaped pixel sensors. The combination of octagon-shaped pixel sensors and square shaped-pixel sensors may permit the pixel sensors to be more densely arranged in the example pixel sensor configuration 1160, for example, by including a square-shaped pixel sensor between a plurality of octagon-shaped pixel sensors. The visible light pixel sensors (e.g., the green pixel sensors 1162, the blue pixel sensors 1164, and the red pixel sensors 1166) may be configured as the physically larger octagon-shaped pixel sensors, and the white pixel sensors 1168 may be configured as the physically smaller square-shaped pixel sensors. This may provide increased color sensitivity while still providing sufficient luminance sensitivity and low-light performance.

As shown in FIG. 11H, an example pixel sensor configuration 1170 may include green pixel sensors 1172, blue pixel sensors 1174, red pixel sensors 1176, and white pixel sensors 1178. The example pixel sensor configuration 1170 may be similar to the example pixel sensor configuration 1160, except that the visible light pixel sensors (e.g., the green pixel sensors 1172, the blue pixel sensors 1174, and the red pixel sensors 1176) are configured as the physically smaller square-shaped pixel sensors, and the white pixel sensors 1178 may be configured as the physically larger octagon-shaped pixel sensors. This configuration may provide increased luminance sensitivity and low-light performance while still providing sufficient color sensitivity.

As indicated above, FIGS. 11A-11H are provided as examples. Other examples may differ from what is described with regard to FIGS. 11A-11H.

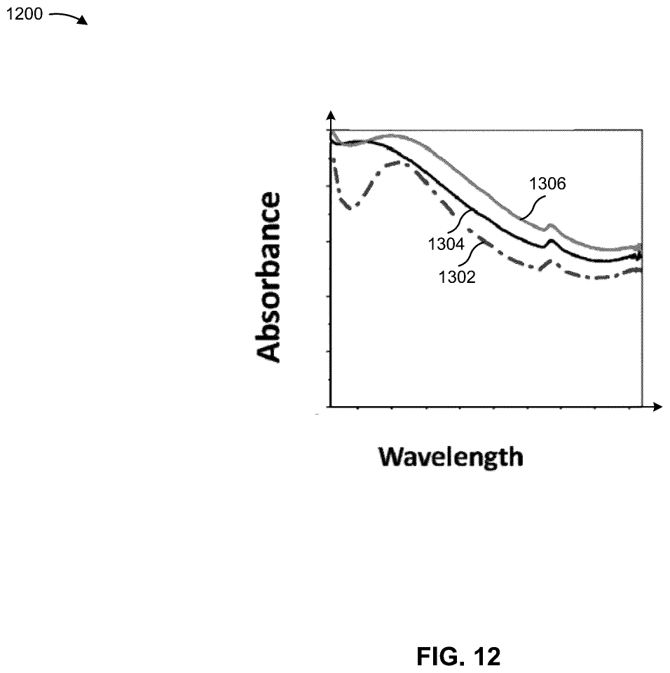

FIG. 12 is a diagram 1200 of example light absorption data described herein. The light absorption data is associated with various combinations of materials for an absorption layer described herein (e.g., the absorption layer 442, 642, 742, and/or 942). As shown in FIG. 12, the diagram 1200 may indicate the absorbance of the various combinations of materials across a wavelength range. The line 1302 may correspond to a combination of tantalum (Ta) and silicon dioxide (SiO₂), in which the ratio between the tantalum and the silicon dioxide is approximately 0.05. The line 1304 may correspond to a combination of tantalum (Ta) and silicon dioxide (SiO₂), in which the ratio between the tantalum and the silicon dioxide is approximately 0.167. The line 1306 may correspond to a combination of tantalum (Ta) and silicon dioxide (SiO₂), in which the ratio between the tantalum and the silicon dioxide is approximately 0.125.

As indicated above, FIG. 12 is provided as an example. Other examples may differ from what is described with regard to FIG. 12.

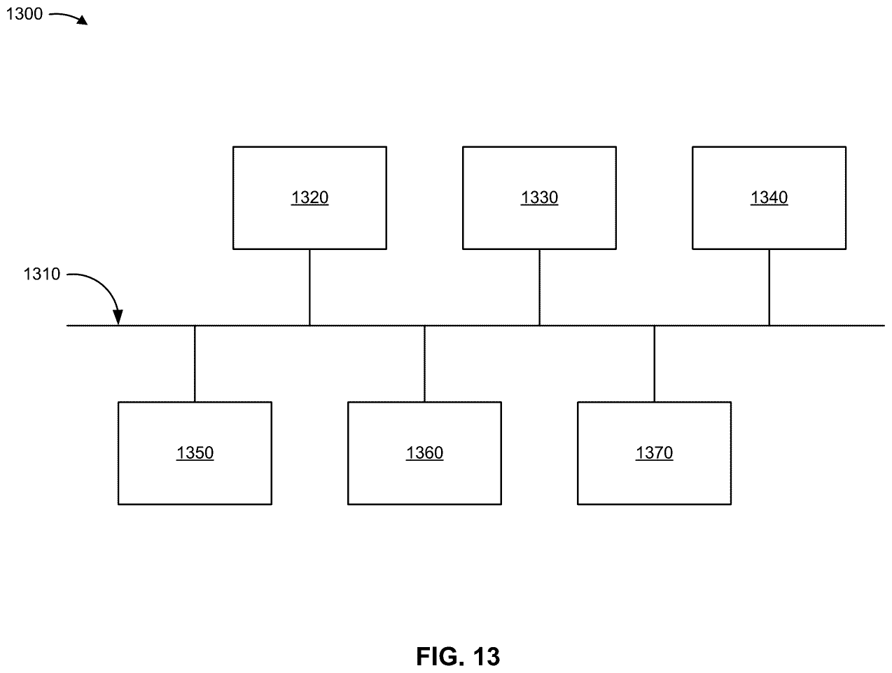

FIG. 13 is a diagram of example components of a device 1300. In some implementations, one or more of the semiconductor processing tools 102-114 and/or the wafer/die transport tool 116 may include one or more devices 1300 and/or one or more components of device 1300. As shown in FIG. 13, device 1300 may include a bus 1310, a processor 1320, a memory 1330, a storage component 1340, an input component 1350, an output component 1360, and a communication component 1370.

Bus 1310 includes a component that enables wired and/or wireless communication among the components of device 1300. Processor 1320 includes a central processing unit, a graphics processing unit, a microprocessor, a controller, a microcontroller, a digital signal processor, a field-programmable gate array, an application-specific integrated circuit, and/or another type of processing component. Processor 1320 is implemented in hardware, firmware, or a combination of hardware and software. In some implementations, processor 1320 includes one or more processors capable of being programmed to perform a function. Memory 1330 includes a random access memory, a read only memory, and/or another type of memory (e.g., a flash memory, a magnetic memory, and/or an optical memory).

Storage component 1340 stores information and/or software related to the operation of device 1300. For example, storage component 1340 may include a hard disk drive, a magnetic disk drive, an optical disk drive, a solid state disk drive, a compact disc, a digital versatile disc, and/or another type of non-transitory computer-readable medium. Input component 1350 enables device 1300 to receive input, such as user input and/or sensed inputs. For example, input component 1350 may include a touch screen, a keyboard, a keypad, a mouse, a button, a microphone, a switch, a sensor, a global positioning system component, an accelerometer, a gyroscope, and/or an actuator. Output component 1360 enables device 1300 to provide output, such as via a display, a speaker, and/or one or more light-emitting diodes. Communication component 1370 enables device 1300 to communicate with other devices, such as via a wired connection and/or a wireless connection. For example, communication component 1370 may include a receiver, a transmitter, a transceiver, a modem, a network interface card, and/or an antenna.

Device 1300 may perform one or more processes described herein. For example, a non-transitory computer-readable medium (e.g., memory 1330 and/or storage component 1340) may store a set of instructions (e.g., one or more instructions, code, software code, and/or program code) for execution by processor 1320. Processor 1320 may execute the set of instructions to perform one or more processes described herein. In some implementations, execution of the set of instructions, by one or more processors 1320, causes the one or more processors 1320 and/or the device 1300 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 13 are provided as an example. Device 1300 may include additional components, fewer components, different components, or differently arranged components than those shown in FIG. 13. Additionally, or alternatively, a set of components (e.g., one or more components) of device 1300 may perform one or more functions described as being performed by another set of components of device 1300.

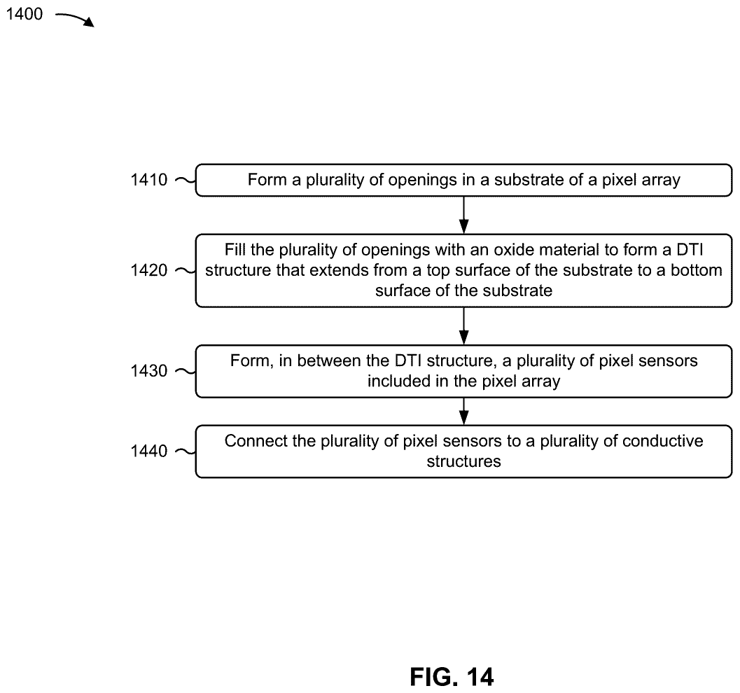

FIG. 14 is a flowchart of an example process 1400 associated with forming a pixel array. In some implementations, one or more process blocks of FIG. 14 may be performed by a one or more semiconductor processing tools (e.g., one or more of the semiconductor processing tools 102-114). Additionally, or alternatively, one or more process blocks of FIG. 14 may be performed by one or more components of device 1300, such as processor 1320, memory 1330, storage component 1340, input component 1350, output component 1360, and/or communication component 1370.

As shown in FIG. 14, process 1400 may include forming a plurality of openings in a substrate of a pixel array (block 1410). For example, one or more of the semiconductor processing tools 102-114 may form a plurality of openings (e.g., the 502, 802, and/or 1002) in a substrate (e.g., the substrate 402, 602, 702, and/or 902) of a pixel array (e.g., the pixel array 200 and/or 300), as described above.

As further shown in FIG. 14, process 1400 may include filling the plurality of openings with an oxide material to form a DTI structure that extends from a top surface of the substrate to a bottom surface of the substrate (block 1420). For example, one or more of the semiconductor processing tools 102-114 may fill the plurality of openings with an oxide material to form a DTI structure (e.g., the DTI structure 204, 306, 436, 636, 736, and/or 936) that extends from a top surface (e.g., the first side 504, 804, and/or 1004) of the substrate to a bottom surface (e.g., the second side 506, 806, and/or 1006) of the substrate, as described above.

As further shown in FIG. 14, process 1400 may include forming, in between the DTI structure, a plurality of pixel sensors included in the pixel array (block 1430). For example, one or more of the semiconductor processing tools 102-114 may form, in between the DTI structure, a plurality of pixel sensors (e.g., the pixel sensors 202, 302, 304, 400, 600, 700, 900, 1102, 1104, 1106, 1108, 1112, 1114, 1116, 1118, 1122, 1124, 1126, 1128, 1132, 1134, 1136, 1138, 1142, 1144, 1146, 1148, 1152, 1154, 1156, 1158, 1162, 1164, 1166, 1168, 1172, 1174, 1176, and/or 1178) included in the pixel array, as described above.

As further shown in FIG. 14, process 1400 may include connecting the plurality of pixel sensors to a plurality of conductive structures (block 1440). For example, one or more of the semiconductor processing tools 102-114 may connect the plurality of pixel sensors to a plurality of conductive structures (e.g., the conductive structures 438, 638, 738, and/or 938), as described above.

Process 1400 may include additional implementations, such as any single implementation or any combination of implementations described below and/or in connection with one or more other processes described elsewhere herein.

In a first implementation, forming the plurality of openings includes etching through the substrate from the top surface (e.g., the first side 504) of the substrate to the bottom surface (e.g., the second side 506) of the substrate to form the plurality of openings (e.g., the openings 502). In a second implementation, alone or in combination with the first implementation, forming the plurality of openings includes etching through the substrate from the bottom surface (e.g., the second side 806) of the substrate to the top surface (e.g., the first side 804) of the substrate to form the plurality of openings (e.g., the openings 802).

In a third implementation, alone or in combination with one or more of the first and second implementations, forming the plurality of openings includes etching into a first portion of the substrate from the top surface (e.g., the first side 1004) of the substrate to form a first portion (e.g., the first portion 1002a) of the plurality of openings (e.g., the openings 1002), and etching into a second portion of the substrate from the bottom surface (e.g., the second side 1006) of the substrate to form a second portion (e.g., the second portion 1002b) of the plurality of openings, where the second portion of the plurality of openings connects to the first portion of the plurality of openings, and filling the plurality of openings includes filling the first portion of the plurality of openings with the oxide material prior to etching into the second portion of the substrate to form the second portion of the plurality of openings, and filling the second portion of the plurality of openings with the oxide material after etching into the second portion of the substrate to form the second portion of the plurality of openings.

In a fourth implementation, alone or in combination with one or more of the first through third implementations, connecting the plurality of pixel sensors to the plurality of conductive structures includes forming a first portion (e.g., the first layer 508) of an IMD layer (e.g., the dielectric layer 444, 644, 744, and/or 944), forming, in the first portion, a plurality of interconnect structures (e.g., the interconnect structures 440, 640, 740, and/or 940) that connect to the plurality of pixel sensors, forming a second portion (e.g., the second layer 512) of the IMD layer over the first portion, forming, in the second portion, an absorption layer (e.g., the absorption layer 442, 642, 742, and/or 942) that connects to the plurality of interconnect structures, and forming, in the second portion, the plurality of conductive structures on the absorption layer.

In a fifth implementation, alone or in combination with one or more of the first through fourth implementations, the plurality of pixel sensors include a set of contiguous red pixel sensors (e.g., red pixel sensors 1106), a first white pixel sensor (e.g., a white pixel sensor 1108) adjacent to the set of contiguous red pixel sensors, a set of contiguous blue pixel sensors (e.g., blue pixel sensors 1104), a second white pixel sensor (e.g., a white pixel sensor 1108) adjacent to the set of contiguous blue pixel sensors, a set of contiguous green pixel sensors (e.g., green pixel sensors 1102), and a third white pixel sensor (e.g., a white pixel sensor 1108) adjacent to the set of contiguous green pixel sensors.

Although FIG. 14 shows example blocks of process 1400, in some implementations, process 1400 may include additional blocks, fewer blocks, different blocks, or differently arranged blocks than those depicted in FIG. 14. Additionally, or alternatively, two or more of the blocks of process 1400 may be performed in parallel.

In this way, a pixel sensor may include a DTI structure that extends the full height of a substrate in which a photodiode of the pixel sensor is included. Incident light entering the pixel sensor at a non-orthogonal angle is absorbed or reflected by the DTI structure along the full height of the substrate. In this way, the DTI structure may reduce, minimize, and/or prevent the incident light from traveling through the pixel sensor and into an adjacent pixel sensor along the full height of the substrate. This may increase the spatial resolution of an image sensor in which the DTI structure is included, may increase the overall sensitivity of the image sensor, may reduce and/or prevent color mixing between pixel sensors of the image sensor, and/or may decrease image noise after color correction. Moreover, the pixel sensor may include extended conductive structures to reflect visible light toward the photodiode of the pixel sensor and an absorption layer on the extended conductive structures to absorb infrared light. The extended conductive structures may be extended to increase the amount of reflected visible light, which may increase the quantum efficiency of the pixel sensor, may increase the low-light color performance of the pixel sensor, and may enable full-color night vision image sensors.

As described in greater detail above, some implementations described herein provide a pixel sensor. The pixel sensor includes a substrate. The pixel sensor includes a photodiode in the substrate. The pixel sensor includes a drain region in the substrate. The pixel sensor includes a DTI structure that extends through the substrate on a first side of the substrate and on a second side of the substrate, where the DTI structure surrounds the photodiode and the drain region.

As described in greater detail above, some implementations described herein provide a method. The method includes forming a plurality of openings in a substrate of a pixel array. The method includes filling the plurality of openings with an oxide material to form a DTI structure that extends from a top surface of the substrate to a bottom surface of the substrate. The method includes forming, in between the DTI structure, a plurality of pixel sensors included in the pixel array. The method includes connecting the plurality of pixel sensors to a plurality of conductive structures.

As described in greater detail above, some implementations described herein provide a pixel array. The pixel array includes a substrate. The pixel array includes a plurality of pixel sensors in the substrate. The pixel array includes a DTI structure in the substrate between the plurality of pixel sensors. The pixel array includes a plurality of conductive structures in a dielectric layer above the substrate, where the plurality of conductive structures are configured to reflect a visible light component of incident light toward photodiodes of the plurality of pixel sensors in the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of openings in a substrate;
filling the plurality of openings with an oxide material to form a deep trench isolation (DTI) structure that extends from a top surface of the substrate to a bottom surface of the substrate;
forming, in between the DTI structure, a plurality of pixel sensors; and
connecting the plurality of pixel sensors to a plurality of conductive structures.

2. The method of claim 1, wherein forming the plurality of openings comprises:
etching through the substrate from the top surface of the substrate to the bottom surface of the substrate.

3. The method of claim 1, wherein forming the plurality of openings comprises:
etching through the substrate from the bottom surface of the substrate to the top surface of the substrate.

4. The method of claim 1, wherein forming the plurality of openings comprises:
etching into a first portion of the substrate from the top surface of the substrate to form a first portion of the plurality of openings; and
etching into a second portion of the substrate from the bottom surface of the substrate to form a second portion of the plurality of openings,
wherein the second portion of the plurality of openings connects to the first portion of the plurality of openings; and
wherein filling the plurality of openings comprises:
filling the first portion of the plurality of openings with the oxide material prior to etching into the second portion of the substrate to form the second portion of the plurality of the openings; and
filling the second portion of the plurality of openings with the oxide material after etching into the second portion of the substrate to form the second portion of the plurality of the openings.

5. The method of claim 1, wherein connecting the plurality of pixel sensors to the plurality of conductive structures comprises:
forming a first portion of an intermetal dielectric layer;
forming, in the first portion, a plurality of interconnect structures that connect to the plurality of pixel sensors;
forming a second portion of the intermetal dielectric layer over the first portion;
forming, in the second portion, an absorption layer that connects to the plurality of interconnect structures; and
forming, in the second portion, the plurality of conductive structures on the absorption layer.

6. The method of claim 1, wherein the plurality of pixel sensors comprises:
a set of contiguous red pixel sensors;
a first white pixel sensor adjacent to the set of contiguous red pixel sensors;
a set of contiguous blue pixel sensors;
a second white pixel sensor adjacent to the set of contiguous blue pixel sensors;
a set of contiguous green pixel sensors; and
a third white pixel sensor adjacent to the set of contiguous green pixel sensors.

7. A method, comprising:
forming a deep trench isolation (DTI) structure in a substrate, wherein the DTI structure extends a full length of the substrate;
forming, in between the DTI structure, a photodiode; and
connecting the photodiode to a conductive structure.

8. The method of claim 7, wherein connecting the photodiode to the conductive structure comprises:
forming an intermetal dielectric layer;
forming, in the intermetal dielectric layer, an interconnect structure that connects to the photodiode; and
connecting, in the intermetal dielectric layer, the conductive structure to the interconnect structure.

9. The method of claim 8, wherein connecting the conductive structure to the interconnect structure comprises:
forming, in the intermetal dielectric layer, an absorption layer on the interconnect structure; and
forming, in the intermetal dielectric layer, the conductive structure over the absorption layer.

10. The method of claim 7, further comprising:
forming, between the DTI structure, a plurality of conductive structures including the conductive structure.

11. The method of claim 10, further comprising:
forming, in the substrate, a drain region; and
connecting a second conductive structure, of the plurality of conductive structures, to the drain region.

12. The method of claim 10, further comprising:
forming, in an oxide layer over the substrate, a transfer gate; and
connecting a second conductive structure, of the plurality of conductive structures, to the transfer gate.

13. A method, comprising:
forming a deep trench isolation (DTI) structure in a substrate, wherein the DTI structure extends a full length of the substrate;
forming, in between the DTI structure, a photodiode;
forming a first dielectric layer over the substrate; and
forming, in the first dielectric layer and between the DTI structure, a plurality of conductive structures.

14. The method of claim 13, wherein the DTI structure is tapered from a first side of the substrate to a second side of the substrate.

15. The method of claim 13, wherein forming the DTI structure in the substrate comprises:
forming a first portion of the DTI structure in a first side of the substrate; and
forming a second portion of the DTI structure in a second side of the substrate.

16. The method of claim 15, wherein the first portion of the DTI structure is tapered from the first side of the substrate to the second side of the substrate, and wherein the second portion of the DTI structure is tapered from the second side of the substrate to the first side of the substrate.

17. The method of claim 15, wherein the second portion of DTI structure is formed after the first portion of the DTI structure, the photodiode, and the plurality of conductive structures are formed.

18. The method of claim 13, further comprising:
forming a grid structure over the substrate,
wherein the grid structure and the first dielectric layer are formed on opposite sides of the substrate.

19. The method of claim 18, further comprising:
forming a second dielectric layer over the substrate,
wherein the grid structure and the second dielectric layer are formed on a same side of the substrate, and
wherein the grid structure is formed in the second dielectric layer.

20. The method of claim 19, further comprising:
forming a color filter layer over the second dielectric layer; and
forming a micro-lens layer over the color filter layer.
